(19) United States
(12) Patent Application Publication
(10) Pub. No.: US 2019/0101676 A1
(43) Pub. Date: Apr. 4, 2019

(54) COLORING COMPOSITION, LIGHT ABSORPTION ANISOTROPIC FILM, LAMINATE, AND IMAGE DISPLAY DEVICE

(71) Applicant: FUJIFILM Corporation, Tokyo (JP)

(72) Inventors: Takashi KATOU, Minami-ashigara-shi (JP); Yumi KATOU, Minami-ashigara-shi (JP); Jyunko IBARAKI, Minami-ashigara-shi (JP)

(73) Assignee: FUJIFILM Corporation, Tokyo (JP)

(21) Appl. No.: 16/145,910

(22) Filed: Sep. 28, 2018

Related U.S. Application Data
(63) Continuation of application No. PCT/JP2017/011442, filed on Mar. 22, 2017.

(30) Foreign Application Priority Data
Mar. 31, 2016 (JP) 2016-071172
Mar. 9, 2017 (JP) 2017-045320

(51) Int. Cl. G02B 5/28; G02B 5/30; C09K 19/60; C09K 19/54; C09K 19/38; H01L 51/00

(52) U.S. Cl. CPC G02B 5/287; G02B 5/3083; C09K 19/601; C09K 19/54; C09K 19/3852; H01L 51/0076; G02F 1/13363; H01L 51/0071; H01L 51/0067; H01L 51/0072; H01L 51/0059; H01L 51/004; H01L 51/0043; H01L 51/005

(57) ABSTRACT

An object of the invention is to provide a coloring composition with which a light absorption anisotropic film having excellent light resistance can be formed, a light absorption anisotropic film, a laminate, and an image display device. A coloring composition according to the invention contains a dichroic dye compound having an azo group; and an oxidant or a singlet oxygen quencher.

### CROSS-REFERENCE TO RELATED APPLICATIONS

This application is a Continuation of PCT International Application No. PCT/JP2017/011442 filed on Mar. 22, 2017, which claims priority under 35 U.S.C. § 119(a) to Japanese Patent Application No. 2016-071172 filed on Mar. 31, 2016 and Japanese Patent Application No. 2017-045320 filed on Mar. 9, 2017. Each of the above applications is hereby expressly incorporated by reference, in its entirety, into the present application.

### BACKGROUND OF THE INVENTION

### 1. Field of the Invention

The present invention relates to a coloring composition, a light absorption anisotropic film, a laminate, and an image display device.

### 2. Description of the Related Art

In a case where an attenuation function, a polarization function, a scattering function, or a shielding function is required in relation to irradiated light including laser light and natural light, a device which is operated by a principle different for each function has been used. Therefore, products corresponding to the above-described functions have also been manufactured through a manufacturing process different for each function.

For example, in liquid crystal displays (LCDs), a linearly polarizing plate or a circularly polarizing plate is used to control optical activity or a birefringent property in display. In addition, in organic light emitting diodes (OLEDs), a circularly polarizing plate is also used to prevent external light from being reflected.

Iodine has been widely used as a dichroic substance in these polarizing plates (polarizing elements). However, a polarizing element using an organic dye as a dichroic substance instead of iodine has also been examined. For example, JP2011-237513A discloses a dichroic dye (dichroic dye compound) having an azo group (claim 9).

### SUMMARY OF THE INVENTION

However, the inventors have examined a coloring composition containing a dichroic dye compound having an azo group described in JP2011-237513A, and found that a light absorption anisotropic film obtained using the coloring composition does not have sufficient light resistance.

Accordingly, an object of the invention is to provide a coloring composition with which a light absorption anisotropic film having excellent light resistance can be formed, a light absorption anisotropic film, a laminate, and an image display device.

The inventors have conducted intensive studies about the above object, and as a result, found that the light resistance of a light absorption anisotropic film to be obtained is improved by adding an oxidant or a singlet oxygen quencher to a coloring composition containing a dichroic dye compound having an azo structure, and completed the invention.

That is, the inventors have found that the above object can be achieved with the following configuration.

[1] A coloring composition comprising: a dichroic dye compound having an azo group; and an oxidant.

[2] The coloring composition according to [1], in which the oxidant has at least one of a quinone structure or an N-oxyl structure.

[3] The coloring composition according to [1] or [2], in which the dichroic dye compound having an azo group has a partial structure represented by Formula (D1), and the oxidant has an N-oxyl structure.

In Formula (D1), Ar¹ and Ar² each independently represent an aromatic hydrocarbon ring or a heterocyclic ring, n represents an integer of 1, 3, or 4, and * represents a bonding position to another group. A plurality of Ar²'s may be the same or different in a case where n is 3 or 4. Regarding Ar¹ and Ar² positioned at both terminals of Formula (D1), all bonding hands at bonding positions * to another group are not directly bonded to an azo group.

[4] The coloring composition according to [2] or [3], in which the N-oxyl structure is a structure represented by Formula (N1) or a structure represented by Formula (N2).

In Formula (N1), R²¹ to R²⁸ each independently represent a hydrogen atom or a substituent. In a case where two or more groups selected from the group consisting of R²¹ to R²⁸ are substituents, two or more substituents may be connected to each other and form a ring.

In Formula (N2), R³¹ to R⁴⁰ each independently represent a hydrogen atom or a substituent. In a case where two or more groups selected from the group consisting of R³¹ to R⁴⁰ are substituents, two or more substituents may be connected to each other and form a ring.

[5] The coloring composition according to [1] or [2], in which the dichroic dye compound having an azo group has a partial structure represented by Formula (D2), and the oxidant has a quinone structure.

In Formula (D2), Ar³ and Ar⁴ each independently represent an aromatic hydrocarbon ring or a heterocyclic ring, and * represents a bonding position to another group. Regarding Ara and Ar⁴, all bonding hands at bonding positions * to another group are not directly bonded to an azo group.

[6] A coloring composition comprising: a dichroic dye compound having an azo group; and a singlet oxygen quencher.

[7] The coloring composition according to [6], in which the singlet oxygen quencher is a diimmonium salt compound.

[8] The coloring composition according to any one of [1] to [7], further comprising: a liquid crystalline compound.

[9] A light absorption anisotropic film which is formed using the coloring composition according to any one of [1] to [8].

[10] A laminate comprising: a base; and the light absorption anisotropic film according to [9] which is formed on the base.

[11] The laminate according to [10], further comprising: a λ/4 plate which is formed on the light absorption anisotropic film.

[12] An image display device comprising: the light absorption anisotropic film according to [9], or the laminate according to [10] or [11].

As shown in the following description, according to the invention, it is possible to provide a coloring composition with which a light absorption anisotropic film having excellent light resistance can be formed, a light absorption anisotropic film, a laminate, and an image display device.

### DESCRIPTION OF THE PREFERRED EMBODIMENTS

Hereinafter, the invention will be described.

The following description of constituent requirements is based on typical embodiments of the invention, but the invention is not limited thereto.

In the invention, a numerical value range expressed using “to” means a range including numerical values before and after “to” as a lower limit value and an upper limit value.

[Coloring Composition]

A coloring composition according to the invention contains: a dichroic dye compound having an azo group; and an oxidant or a singlet oxygen quencher.

According to the coloring composition of the invention, a light absorption anisotropic film having excellent light resistance can be formed. The detailed reason for this is not clear yet, but presumed as follows.

The decomposition of a dichroic dye compound (also simply referred to as “azo dye”) having an azo group by light irradiation has been thought to proceed mainly oxidatively.

Accordingly, the inventors have added a phenol compound and an amine compound as antioxidants to a composition containing an azo dye, but found that a light absorption anisotropic film to be obtained does not have sufficient light resistance.

Based on such knowledge, the inventors have examined various additives and disclosed that the light resistance of a light absorption anisotropic film can be improved by adding an oxidant. The addition of an oxidant is thought to promote the decomposition of the azo dye and to deteriorate the light resistance according to a decomposition mechanism of the azo dye. However, from the result that the light resistance of a light absorption anisotropic film is improved with the addition of an oxidant, the decomposition of the azo dye by light irradiation is presumed to proceed reductively. From this, a light resistance improving mechanism using an oxidant is presumed to be that in an excitation state in which the azo dye is photoexcited, the oxidant rapidly receives excited electrons, and thus the excitation state is deactivated.

Moreover, the inventors have conducted studies, and found that other than the oxidant, a singlet oxygen quencher also acts to improve the light resistance of a light absorption anisotropic film. That is, in a case where oxygen is excited and becomes singlet oxygen, oxidation power increases. It is presumed that oxidation by the singlet oxygen cannot be suppressed with the above-described antioxidants, and the decomposition of the azo dye proceeds. Accordingly, it is thought that the singlet oxygen can be deactivated with the addition of a singlet oxygen quencher, and the light resistance of a light absorption anisotropic film is improved.

A coloring composition according to the invention will be described for each embodiment. In the following description, an aspect in which an oxidant is contained in the coloring composition according to the invention will be described as a first embodiment, and an aspect in which a singlet oxygen quencher is contained will be described as a second embodiment.

### First Embodiment

A coloring composition according to a first embodiment contains a dichroic dye compound having an azo group and an oxidant.

<Oxidant>

The coloring composition according to the first embodiment contains an oxidant.

An oxidant refers to general substances having an oxidation action. More specifically, an oxidant refers to substances which impart oxygen, substances which take hydrogen, and substances which increase the positive oxidation number, and it can be comprehensively defined as a substance which takes electrons.

From the viewpoint of further improving the light resistance of a light absorption anisotropic film, as the oxidant, an oxidant having at least one of a quinone structure or an N-oxyl structure is preferably used.

The content of the oxidant is preferably 0.1 to 100 parts by mass, more preferably 1 to 50 parts by mass, and even more preferably 1 to 40 parts by mass with respect to 100 parts by mass of the dichroic dye compound having an azo group in the coloring composition. In a case where the content of the oxidant is within the above range, the light resistance of a light absorption anisotropic film is further improved.

The oxidants may be used alone or in combination of two or more kinds thereof.

(Oxidant Having Quinone Structure)

As the oxidant having a quinone structure, a compound represented by Formula (A) is preferable from the viewpoint of further improving the light resistance of a light absorption anisotropic film.

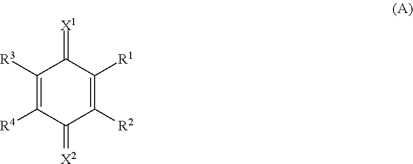

In Formula (A), R¹, R², R³, and R⁴ each independently represent a hydrogen atom or a substituent.

In a case where R¹ and R², or R³ and R⁴ are both substituents, R¹ and R², or R³ and R⁴ may be connected to each other and form an unsaturated condensed ring. The unsaturated condensed ring may have a substituent, and the substituent is similar to the substituent described in relation to R¹ to R⁴.

X¹ and X² each independently represent an oxygen atom, a sulfur atom, a ═NR^{1X} group, or a ═CR^{2X}R^{3X} group. R^{1X}, R^{2X}, and R^{3X} each independently represent a hydrogen atom or a substituent. The substituent related to R^{1X} to R^{3X} is similar to the substituent described in relation to R¹ to R⁴.

Specific examples of the substituents represented by R¹ to R⁴ include an alkyl group, an alkenyl group, an aralkyl group, an aryl group, a heterocyclic group, a halogen atom, a cyano group, a nitro group, a mercapto group, a hydroxy group, an alkoxy group, an aryloxy group, an alkylthio group, an arylthio group, an acyloxy group, an amino group, an alkylamino group, a carbonamide group, a sulfonamide group, a sulfamoylamino group, an oxycarbonylamino group, an oxysulfonylamino group, a ureido group, a thioureido group, an acyl group, an oxycarbonyl group, a carbamoyl group, a sulfonyl group, a sulfinyl group, a sulfamoyl group, a carboxy group (including salt), and a sulfo group (including salt). These may be further substituted by the above substituents.

More specific examples of the substituents represented by R¹, R², and R³ will be shown. The alkyl group is preferably a linear, branched, or cyclic alkyl group having 1 to 18 carbon atoms, and examples thereof include methyl, ethyl, propyl, isopropyl, t-butyl, cyclopentyl, cyclohexyl, 2-hydroxyethyl, 3-hydroxypropyl, 4-hydroxybutyl, 3-methoxypropyl, 2-aminoethyl, acetoamidemethyl, 2-acetoamidethyl, carboxymethyl, 2-carboxyethyl, 2-sulfoethyl, ureidomethyl, 2-ureidoethyl, carbamoylmethyl, 2-carbamoylethyl, 3-carbamoylpropyl, pentyl, hexyl, octyl, decyl, undecyl, dodecyl, hexadecyl, and octadecyl.

The alkenyl group is preferably a linear, branched, or cyclic alkenyl group having 2 to 18 carbon atoms, and examples thereof include vinyl, allyl, 1-propenyl, 2-pentenyl, 1,3-butadienyl, 2-octenyl, and 3-dodecenyl.

The aralkyl group preferably has 7 to 10 carbon atoms, and examples thereof include benzyl.

The aryl group preferably has 6 to 10 carbon atoms, and examples thereof include phenyl, naphthyl, p-dibutylaminophenyl, and p-methoxyphenyl.

The heterocyclic group is preferably a 5- or 6-membered saturated or unsaturated heterocyclic group including a carbon atom, a nitrogen atom, an oxygen atom, or a sulfur atom. The number of hetero atoms constituting a ring and the number of kinds of elements may be one or more, respectively. Examples of the heterocyclic group include furyl, benzofuryl, pyranyl, pyrrolyl, imidazolyl, isoxazolyl, pyrazolyl, benzotriazolyl, pyridyl, pyrimidyl, pyridazinyl, thienyl, indolyl, quinolyl, phthalazinyl, quinoxalinyl, pyrrolidinyl, pyrrolinyl, imidazolidinyl, imidazolinyl, pyrazolidinyl, piperidyl, piperadinyl, indolinyl, and morpholinyl.

Examples of the halogen atom include a fluorine atom, a chlorine atom, and a bromine atom.

The alkoxy group preferably has 1 to 18 carbon atoms, and examples thereof include methoxy, ethoxy, propoxy, isopropoxy, butoxy, 2-methoxyethoxy, 2-methane sulfonylethoxy, pentyloxy, hexyloxy, octyloxy, undecyloxy, dodecyloxy, hexadecyloxy, and octadecyloxy.

The aryloxy group preferably has 6 to 10 carbon atoms, and examples thereof include phenoxy and p-methoxyphenoxy.

The alkylthio group preferably has 1 to 18 carbon atoms, and examples thereof include methylthio, ethylthio, octylthio, undecylthio, dodecylthio, hexadecylthio and octadecylthio.

The arylthio group preferably has 6 to 10 carbon atoms, and examples thereof include phenylthio and 4-methoxyphenylthio.

The acyloxy group preferably has 1 to 18 carbon atoms, and examples thereof include acetoxy, propanoyloxy, pentanoyloxy, octanoyloxy, dodecanoyloxy and octadecanoyloxy.

The alkylamino group preferably has 1 to 18 carbon atoms, and examples thereof include methylamino, dimethylamino, diethylamino, dibutylamino, octylamino, dioctylamino and undecylamino.

The carbonamide group preferably has 1 to 18 carbon atom, and examples thereof include formamide, acetamide, acetylmethylamino, acetyloctylamino, acetyldecylamino, acetylundecylamino, acetyloctadecylamino, propanoylamino, pentanoylamino, octanoylamino, octanoylmethylamino, dodecanoylamino, dodecanoylmethylamino, and octadecanoylamino.

The sulfonamide group preferably has 1 to 18 carbon atoms, and examples thereof include methanesulfonamide, ethanesulfonamide, propyl sulfonamide, 2-methoxyethylsulfonamide, 3-aminopropylsulfonamide, 2-acetamideethylsulfonamide, octylsulfonamide, and undecylsulfonamide.

The oxycarbonylamino group preferably has 1 to 18 carbon atoms, and examples thereof include methoxycarbonylamino, ethoxycarbonylamino, octyloxycarbonylamino, and undecyloxycarbonylamino.

The oxysulfonylamino group preferably has 1 to 18 carbon atoms, and examples thereof include methoxysulfonylamino, ethoxysulfonylamino, octyloxysulfonylamino, and undecyloxysulfonylamino.

The sulfamoylamino group preferably has 0 to 18 carbon atoms, and examples thereof include methylsulfamoylamino, dimethylsulfamoylamino, ethylsulfamoylamino, propylsulfamoylamino, octylsulfamoylamino, and undecylsulfamoylamino.

The ureido group preferably has 1 to 18 carbon atoms, and examples thereof include ureido, methylureido, N,N-dimethylureido, octylureido, and undecylureido.

The thioureido group preferably has 1 to 18 carbon atoms, and examples thereof include thioureido, methylthioureido, N,N-dimethylthioureido, octylthioureido, and undecylthioureido.

The acyl group preferably has 1 to 18 carbon atoms, and examples thereof include acetyl, benzoyl, octanoyl, decanoyl, undecanoyl, and octadecanoyl.

The oxycarbonyl group preferably has 1 to 18 carbon atoms, and examples thereof include methoxycarbonyl, ethoxycarbonyl, octyloxycarbonyl, and undecyloxycarbonyl.

The carbamoyl group preferably has 1 to 18 carbon atoms, and examples thereof include carbamoyl, N,N-dimethylcarbamoyl, N-ethylcarbamoyl, N-octylcarbamoyl, N,N-dioctylcarbamoyl, and N-undecylcarbamoyl.

The sulfonyl group preferably has 1 to 18 carbon atoms, and examples thereof include methanesulfonyl, ethanesulfonyl, 2-chloroethanesulfonyl, octanesulfonyl, and undecanesulfonyl.

The sulfinyl group preferably has 1 to 18 carbon atoms, and examples thereof include methanesulfinyl, ethanesulfinyl, and octanesulfinyl.

The sulfamoyl group preferably has 0 to 18 carbon atoms, and examples thereof include sulfarmoyl, dimethylsulfamoyl, ethylsulfamoyl, octylsulfamoyl, dioctylsulfamoyl, and undecylsulfamoyl.

X¹ and X² each independently represent an oxygen atom, a sulfur atom, a ═NR^{1X} group, or a ═CR^{2X}R^{3X} group, and preferably an oxygen atom or a ═C(R^{2X})(R^{3X}) group. It is more preferable that X¹ and X² be both oxygen atoms or ═C(R^{2X})(R^{3X}) groups.

R^{1X} to R^{3X} each independently represent a hydrogen atom or a substituent, and specific examples of the substituent are similar to those described in relation to R¹ to R⁴.

In a case where X¹ and X² are both oxygen atoms, R¹ to R⁴ each independently preferably represent an alkyl group, an aryl group, a halogen atom, a cyano group, a nitro group, an alkoxy group, an alkylthio group, an amino group, an alkylamino group, a carbonamide group, a sulfonamide group, a sulfamoylamino group, an oxycarbonylamino group, an oxysulfonylamino group, a ureido group, a thioureido group, an acyl group, an oxycarbonyl group, a carbamoyl group, a sulfonyl group, a sulfinyl group, a sulfamoyl group, a group obtained by combining the above groups, and a hydrogen atom, and more preferably represent an alkyl group, an aryl group, a halogen atom, a cyano group, an alkylthio group, a carbonamide group, a group obtained by combining the above groups, and a hydrogen atom.

R^{2X} and R^{3X} each independently represent a hydrogen atom or a substituent, preferably a substituent, more preferably a halogen atom, a cyano group, an acyl group, an oxycarbonyl group, or a sulfonyl group, and even more preferably a cyano group. It is particularly preferable that R^{2X} and R^{3X} be both cyano groups.

As the compound represented by Formula (A), a compound in which X¹ and X² are both ═CR^{2X}R^{3X} groups, and R^{2X} and R^{3X} are both cyano groups can also be preferably used. As such a compound, specifically, a compound represented by Formula (AQ) is preferably used.

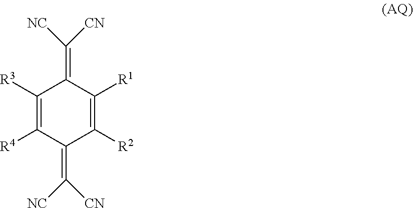

In Formula (AQ), R¹ to R⁴ may be the same or different, and are synonymous with R¹ to R⁴ in Formula (A).

Among compounds represented by Formula (AQ), compounds represented by Formula (AQ-1) or Formula (AQ-2) are preferable.

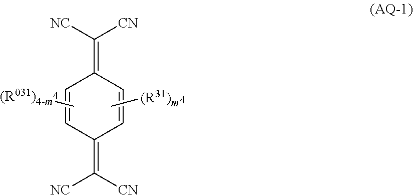

In Formula (AQ-1), R³¹ represents a halogen atom, a cyano group, a phenyl group, an alkoxy group, an alkylthio group, a carbonamide group, a sulfonamide group, a ureido group, an acyl group, or an oxycarbonyl group, and examples of R⁰³¹ are the same as in the description of R¹ to R⁴. m⁴ represents an integer of 1 to 4. In a case where m⁴ or 4-m⁴ represents an integer of 2 or more, a plurality of R³¹'s and a plurality of R⁰³¹'s may be the same or different, respectively.

Regarding R³¹ and R⁰³¹ in Formula (AQ-1), preferable combinations thereof will be described hereinbelow.

A combination in which R³¹ is a halogen atom, a cyano group, an alkoxy group having 1 to 18 carbon atoms, an acyl group having 1 to 18 carbon atoms, or an oxycarbonyl group having 1 to 18 carbon atoms, and R⁰³¹ is a hydrogen atom or an alkyl group having 1 to 18 carbon atoms or “4-m⁴” representing the number of R⁰³¹ is 0 (that is, there is no substitution with R⁰³¹) is preferable.

More preferable is a combination in which R³¹ is an alkoxy group having 1 to 18 carbon atoms or a halogen atom, and R⁰³¹ is a hydrogen atom or “4-m⁴” representing the number of R⁰³¹ is 0.

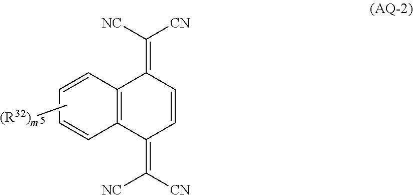

In Formula (AQ-2), R³² represents a hydrogen atom or a substituent. Here, examples of the substituent include the substituent described in relation to R¹ to R⁴. m⁵ represents an integer of 0 to 6. In a case where m⁵ represents an integer of 2 or more, a plurality of R³²'s may be the same or different.

R³² in Formula (AQ-2) is preferably a hydrogen atom, an alkyl group, a halogen atom, a cyano group, an alkoxy group, an alkylthio group, a carbonamide group, a sulfonamide group, a ureido group, and an acyl group, more preferably a hydrogen atom, an alkyl group having 8 to 18 carbon atoms, a halogen atom, a cyano group, an alkoxy group having 8 to 18 carbon atoms, an alkylthio group having 8 to 18 carbon atoms, a carbonamide group having 8 to 18 carbon atoms, a sulfonamide group having 8 to 18 carbon atoms, a ureido group having 8 to 18 carbon atoms, and an acyl group having 8 to 18 carbon atoms, even more preferably a hydrogen atom, an alkyl group having 8 to 18 carbon atoms, a fluorine atom, a chlorine atom, a bromine atom, a cyano group, and an alkoxy group having 8 to 18 carbon atoms, and particularly preferably a hydrogen atom.

Specific examples of the oxidant having a quinone structure are as follows, but not limited thereto.

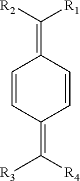

| No. | R¹ | R² | R³ | R⁴ |
|---|---|---|---|---|
| A-1 | CN | CN | CN | CN |
| A-2 | ″ | CO₂CH₃ | ″ | CO₂CH₃ |
| A-3 | ″ | CO₂C₂H₅ | ″ | CO₂C₂H₅ |
| A-4 | ″ | CO₂C₄H₉ | ″ | CO₂C₄H₉ |
| A-5 | ″ | CO₂C₁₀H₂₁ | ″ | CO₂C₁₀H₂₁ |
| A-6 | ″ | CO₂C₁₁H₂₃ | ″ | CO₂C₁₁H₂₃ |
| A-7 | CO₂C₁₁H₂₃ | ″ | CO₂C₁₁H₂₃ | ″ |
| A-8 | CO₂C₂H₅ | CO₂C₂H₅ | CO₂C₂H₅ | CO₂C₂H₅ |
| A-9 | Cl | Cl | Cl | Cl |
| A-10 | COCH₃ | COCH₃ | COCH₃ | COCH₃ |
| A-11 | COC₁₁H₂₃ | COC₁₁H₂₃ | COC₁₁H₂₃ | COC₁₁H₂₃ |
| A-12 | SO₂C₂H₅ | SO₂C₂H₅ | SO₂C₂H₅ | SO₂C₂H₅ |

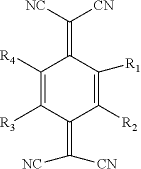

| No. | R₁ | R₂ | R₃ | R₄ |
|---|---|---|---|---|
| A-13 | F | F | F | F |
| A-14 | CN | H | CN | H |
| A-15 | 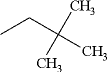 | ″ | 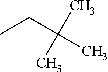 | ″ |
| A-16 | CO₂C₁₁H₂₃ | ″ | CO₂C₁₁H₂₃ | ″ |
| A-17 | Cl | NHCOC₁₁H₂₃ | Cl | NHCOC₁₁H₂₃ |
| A-18 | ″ | 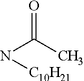 | ″ | 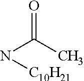 |

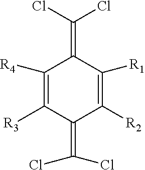

| No. | R₁ | R₂ | R₃ | R₄ |
|---|---|---|---|---|
| A-19 | Cl | Cl | Cl | Cl |
| A-20 | ″ | H | ″ | H |
| A-21 | CN | ″ | H | ″ |
| A-22 | Cl | NHCOC₁₁H₂₃ | Cl | NHCOC₁₁H₂₃ |

| | |
|---|---|
| A-23 | 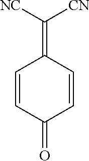 [SMILES: N#CC(C#N)=C1C=CC(=O)C=C1] |

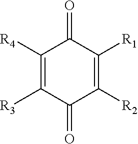

| No. | R₁ | R₂ | R₃ | R₄ |
|---|---|---|---|---|
| A-24 | Cl | Cl | Cl | Cl |
| A-25 | ″ | H | H | Cl |
| A-26 | ″ | ″ | Cl | H |
| A-27 | Br | Br | Br | Br |
| A-28 | F | F | F | F |
| A-29 | Cl | Cl | Cl | NHCOC₁₁H₂₃ |
| A-30 | ″ | ″ | ″ | 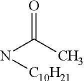 |
| A-31 | ″ | NHCOC₅H₁₁ | ″ | NHCOC₅H₁₁ |
| A-32 | ″ | NHCOC₁₁H₂₃ | ″ | NHCOC₁₁H₂₃ |
| A-33 | ″ | 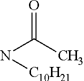 | ″ | 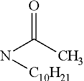 |
| A-34 | ″ | NHCONHC₂H₅ | ″ | NHCONHC₂H₅ |
| A-35 | ″ | NHSO₂CH₃ | ″ | NHSO₂CH₃ |

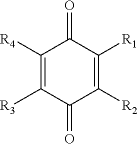

| No. | R₁ | R₂ | R₃ | R₄ |
|---|---|---|---|---|
| A-36 | Cl | NHSO₂C₈H₁₇ | Cl | NHSO₂C₈H₁₇ |
| A-37 | ″ | CO₂C₂H₅ | ″ | CO₂C₂H₅ |
| A-38 | ″ | CO₂C₁₀H₂₁ | ″ | CO₂C₁₀H₂₁ |
| A-39 | ″ | CONHC₈H₁₇ | ″ | CONHC₈H₁₇ |
| A-40 | ″ | H | 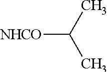 | H |
| A-41 | ″ | ″ | —SC₁₂H₂₅ | ″ |
| A-42 | ″ | ″ | 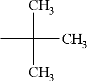 | ″ |
| A-43 | ″ | ″ | NHCOC₁₅H₃₁ | ″ |
| A-44 | Cl | ″ | H | ″ |
| A-45 | H | ″ | ″ | ″ |
| A-46 | —CO₂C₂H₅ | —CO₂C₂H₅ | —CO₂C₂H₅ | —CO₂C₂H₅ |
| A-47 | —COC₈H₁₇ | —COC₈H₁₇ | —COC₈H₁₇ | —COC₈H₁₇ |

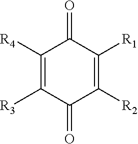

| No. | R₁ | R₂ | R₃ | R₄ |
|---|---|---|---|---|
| A-48 | —CO₂C₈H₁₇ | H | —CO₂C₈H₁₇ | H |
| A-49 | —NHCOC₁₅H₃₁ | ″ | H | ″ |
| A-50 | —SC₁₂H₂₅ | ″ | ″ | ″ |
| A-51 | Cl | Cl | CN | CN |
| A-52 | ″ | ″ | ″ | —OC₈H₁₇ |

| | |
|---|---|
| A-53 | 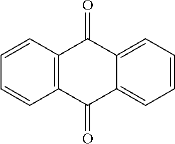 [SMILES: O=C1c2ccccc2C(=O)c2ccccc21] |
| A-54 | 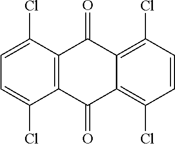 [SMILES: O=C1c2c(Cl)ccc(Cl)c2C(=O)c2c(Cl)ccc(Cl)c21] |
| A-55 | 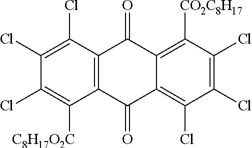 |
| A-56 | 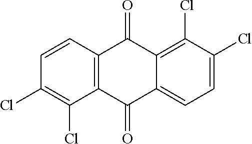 [SMILES: O=C1c2ccc(Cl)c(Cl)c2C(=O)c2ccc(Cl)c(Cl)c21] |
| A-57 | 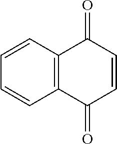 [SMILES: O=C1C=CC(=O)c2ccccc21] |
| A-58 | 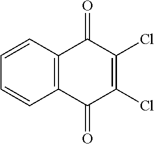 [SMILES: O=C1C(Cl)=C(Cl)C(=O)c2ccccc21] |
| A-59 | 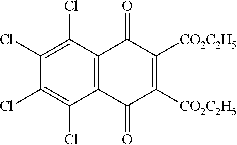 [SMILES: CCOC(=O)C1=C(C(=O)OCC)C(=O)c2c(Cl)c(Cl)c(Cl)c(Cl)c2C1=O] |
| A-60 | 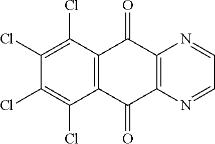 [SMILES: O=C1c2nccnc2C(=O)c2c(Cl)c(Cl)c(Cl)c(Cl)c21] |
| A-61 | 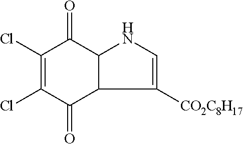 |
| A-62 | 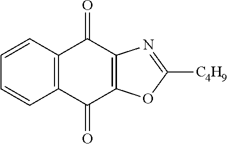 |
| A-63 | 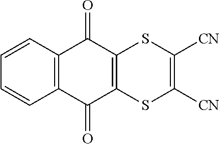 [SMILES: N#Cc1sc2c(=O)c3ccccc3c(=O)c=2sc1C#N] |

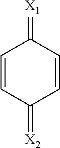

| No. | X₁ | X₂ |
|---|---|---|
| A-64 | S | S |
| A-65 | NC₈H₁₇ | NH |
| A-66 | ″ | NC₈H₁₇ |
| A-67 | S | O |
| A-68 | N⁺(C₅H₁₁)₂ | O |
| A-69 | CCl₂ | C(CN)₂ |

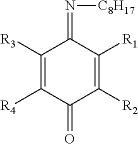

| No. | R₁ | R₂ | R₃ | R₄ |
|---|---|---|---|---|
| A-70 | Cl | Cl | Cl | Cl |
| A-71 | H | ″ | ″ | H |
| A-72 | ″ | CN | CN | ″ |
| A-73 | NHCOC₁₀H₂₁ | Cl | Cl | NHCOC₁₀H₂₁ |

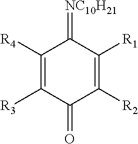

| No. | R₁ | R₂ | R₃ | R₄ |
|---|---|---|---|---|
| A-74 | Cl | Cl | Cl | Cl |
| A-75 | H | ″ | ″ | H |
| A-76 | C₈H₁₇ | ″ | ″ | ″ |
| A-77 | Cl | NHCOC₁₀H₂₁ | ″ | ″ |

| | |
|---|---|
| A-78 | 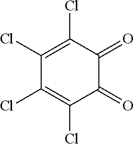 [SMILES: O=C1C(=O)C(Cl)=C(Cl)C(Cl)=C1Cl] |
| A-79 | 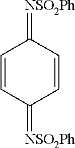 |
| A-80 | 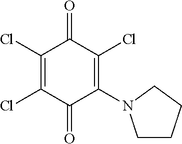 [SMILES: O=C1C(Cl)=C(Cl)C(=O)C(N2CCCC2)=C1Cl] |
| A-110 | 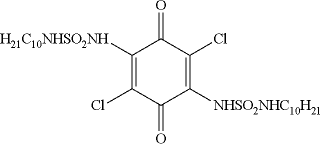 |
| A-111 | 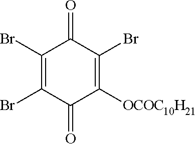 |
| A-112 | 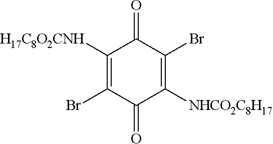 |
| A-113 | 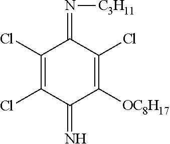 |
| A-114 | 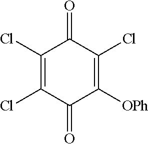 [SMILES: O=C1C(Cl)=C(Cl)C(=O)C(Oc2ccccc2)=C1Cl] |
| A-115 | 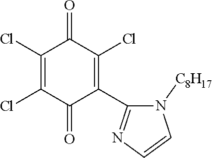 |
| A-116 | 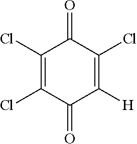 [SMILES: O=C1C=C(Cl)C(=O)C(Cl)=C1Cl] |

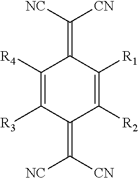

| No. | R₁ | R₂ | R₃ | R₄ |
|---|---|---|---|---|
| A-117 | C₁₈H₃₇ | H | H | H |
| A-118 | F | ″ | ″ | ″ |
| A-119 | OCH₃ | ″ | ″ | ″ |
| A-120 | Cl | ″ | ″ | ″ |
| A-121 | Br | ″ | ″ | ″ |
| A-122 | CH₂Ph | ″ | ″ | ″ |
| A-123 | CH₂CO₂H | ″ | ″ | ″ |
| A-124 | OCH₃ | ″ | OCH₃ | ″ |
| A-125 | OC₂H₅ | ″ | SCH₃ | ″ |
| A-126 | CH₃ | ″ | Cl | ″ |
| A-127 | CH₃ | ″ | Br | ″ |
| A-128 | Cl | ″ | Cl | ″ |

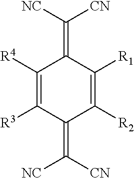

| No. | R₁ | R₂ | R₃ | R₄ |
|---|---|---|---|---|
| A-129 | Br | H | Br | H |
| A-130 | CH₃ | ″ | CH₃ | ″ |
| A-131 | F | ″ | F | ″ |
| A-132 | CO₂C₈H₁₇ | ″ | H | ″ |
| A-133 | COC₁₁H₂₃ | ″ | ″ | ″ |
| A-134 | Br | ″ | OCH₂CH₂OH | ″ |

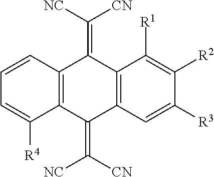

| No. | R₁ | R₂ | R₃ | R₄ |
|---|---|---|---|---|
| A-135 | H | B | H | H |
| A-136 | ″ | CO₂C₈H₁₇ | ″ | ″ |
| A-137 | Cl | H | ″ | Cl |
| A-138 | H | CN | ″ | H |
| A-139 | ″ | —C₈H₁₇ | —C₈H₁₇ | ″ |

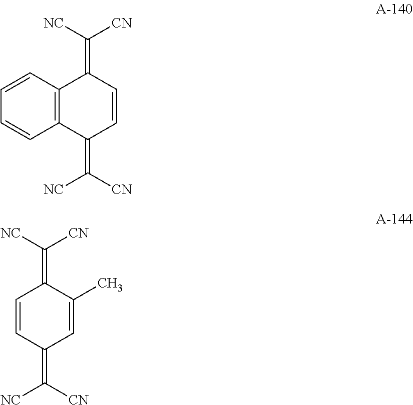

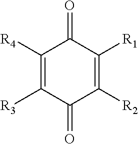

| No. | R₁ | R₂ | R₃ | R₄ |
|---|---|---|---|---|
| A-145 | —SO₂C₂H₅ | —SO₂C₂H₅ | —SO₂C₂H₅ | —SO₂C₂H₅ |
| A-146 | ″ | ″ | ″ | —OC₂H₅ |
| A-147 | ″ | —OC₂H₅ | ″ | ″ |
| A-148 | ″ | —SO₂C₂H₅ | ″ | —Cl |
| A-149 | ″ | —H | ″ | —H |
| A-150 | —SOC₂H₅ | —SOC₂H₅ | —SOC₂H₅ | —SOC₂H₅ |
| A-151 | —SO₂C₂H₅ | —SO₂C₂H₅ | —SO₂C₂H₅ | —CH₃ |
| A-152 | —SO₂Ph | —SO₂Ph | —SO₂Ph | —Cl |
| A-153 | ″ | ″ | —CN | —CN |
| A-154 | ″ | —H | ″ | ″ |
| A-155 | ″ | —Cl | ″ | ″ |
| A-156 | ″ | —SO₂Ph | —SO₂Ph | —SO₂Ph |

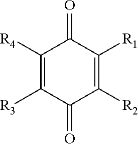

| No. | R₁ | R₂ | R₃ | R₄ |
|---|---|---|---|---|
| A-157 | —SCF₃ | —SCF₃ | —SCF₃ | —SCF₃ |
| A-158 | —SOCF₃ | —SOCF₃ | —SOCF₃ | —SOCF₃ |
| A-159 | —SO₂CF₃ | —SO₂CF₃ | —SO₂CF₃ | —SO₂CF₃ |
| A-160 | ″ | —H | ″ | —H |
| A-161 | —H | ″ | ″ | ″ |
| A-162 | —Cl | —SO₂CF₃ | ″ | —Cl |
| A-163 | —SO₂C₈H₁₇ | —SO₂C₈H₁₇ | —SO₂C₈H₁₇ | —SO₂C₈H₁₇ |

| | |
|---|---|
| A-164 | 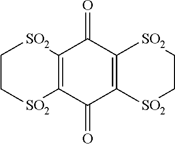 [SMILES: O=C1C2=C(C(=O)C3=C1S(=O)(=O)CCS3(=O)=O)S(=O)(=O)CCS2(=O)=O] |
| A-165 | 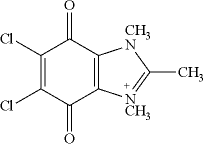 |
| A-166 | 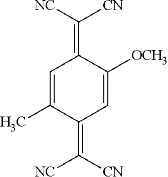 [SMILES: COc1cc(=C(C#N)C#N)c(C)cc1=C(C#N)C#N] |
| A-167 | 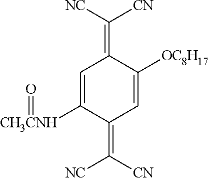 |
| A-168 | 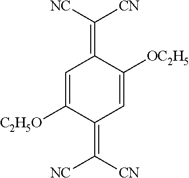 |

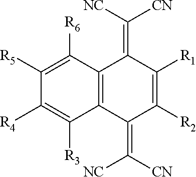

| No. | R₁ | R₂ | R₃ | R₄ | R₅ | R₆ |
|---|---|---|---|---|---|---|
| A-169 | —CH₃ | —H | —H | —H | —H | —H |
| A-170 | ″ | —Cl | ″ | ″ | ″ | ″ |
| A-171 | ″ | —CH₃ | ″ | ″ | ″ | ″ |
| A-172 | —H | —H | ″ | —OCH₃ | ″ | ″ |
| A-173 | ″ | ″ | ″ | —C₈H₁₇ | ″ | ″ |
| A-174 | ″ | ″ | ″ | —Cl | —Cl | ″ |
| A-175 | ″ | ″ | ″ | —SC₈H₁₇ | —H | ″ |
| A-176 | ″ | ″ | ″ | —NHCOC₈H₁₇ | ″ | ″ |

| | |
|---|---|
| A-177 | 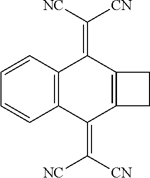 [SMILES: N#CC(C#N)=c1c2c(c(=C(C#N)C#N)c3ccccc13)CC2] |
| A-178 | 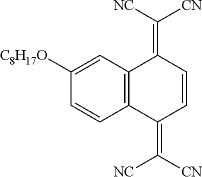 |
| A-179 | 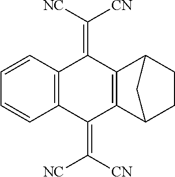 [SMILES: N#CC(C#N)=c1c2c(c(=C(C#N)C#N)c3ccccc13)C1CCC2C1] |
| A-180 | 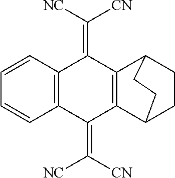 [SMILES: N#CC(C#N)=c1c2c(c(=C(C#N)C#N)c3ccccc13)C1CCC2CC1] |

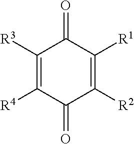

| No. | R¹ | R² | R³ | R⁴ |
|---|---|---|---|---|
| A-181 | CH₃ | H | H | H |
| A-182 | t-Bu | H | H | H |
| A-183 | Ph | H | H | H |
| A-184 | Cl | Cl | H | H |
| A-185 | CH₃ | H | CH₃ | H |
| A-186 | NHCOCH₃ | H | H | H |
| A-187 | NHCOCH₂SC₁₂H₂₅ | CN | H | H |

(Oxidant Having N-Oxyl Structure)

As the oxidant having an N-oxyl structure, a compound represented by Formula (N) is preferable from the viewpoint of improving the light resistance of a light absorption anisotropic film.

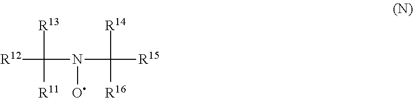

In Formula (N), R¹¹, R₁₂, R₁₅ and R¹⁶ each independently represent a hydrogen atom, an alkyl group, or an aryl group.

In Formula (N), R¹³ and R¹⁴ each independently represent an alkyl group, an aryl group, or an alkoxy group. In a case where R¹³ and R¹⁴ are alkyl groups or alkoxy groups, R¹³ and R¹⁴ may be connected to each other and form a ring.

The alkyl group related to R¹¹ to R¹⁶ is preferably a linear, branched, or cyclic alkyl group having 1 to 18 carbon atoms, and examples thereof include methyl, ethyl, propyl, isopropyl, t-butyl, cyclopentyl, cyclohexyl, pentyl, hexyl, octyl, decyl, undecyl, dodecyl, hexadecyl, and octadecyl.

Among these, as the alkyl group related to R¹¹ to R¹⁶, a linear, branched, or cyclic alkyl group having 1 to 6 carbon atoms is preferable, a linear or branched alkyl group having 1 to 6 carbon atoms is more preferable, and a linear alkyl group having 1 to 6 carbon atoms is even more preferable.

The aryl group related to R¹¹ to R¹⁶ preferably has 6 to 10 carbon atoms is preferable, and examples thereof include phenyl and naphthyl.

The alkoxy group related to R¹³ and R¹⁴ preferably has 1 to 18 carbon atoms, and examples thereof include methoxy, ethoxy, propoxy, isopropoxy, butoxy, pentyloxy, hexyloxy, octyloxy, undecyloxy, dodecyloxy, hexadecyloxy, and octadecyloxy.

Among these, as the alkoxy group related to R¹³ and R¹⁴, an alkoxy group having 1 to 6 carbon atoms is preferable.

In a case where R¹³ and R¹⁴ are alkyl groups or alkoxy groups, R¹³ and R¹⁴ may be connected to each other and form a ring. In this case, Formula (N) has a saturated heterocyclic skeleton (saturated nitrogen-containing heterocyclic skeleton) containing at least a nitrogen atom.

Such a saturated nitrogen-containing heterocyclic skeleton is preferably 5-, 6-, 7-, or 8-membered, and more preferably 5- or 6-membered.

Examples of the saturated nitrogen-containing heterocyclic skeleton include a pyrrolidine skeleton, a piperidine skeleton, a morpholine skeleton, and an oxazolidine skeleton.

The heterocyclic ring in the saturated heterocyclic skeleton may have a substituent. Specific examples of the substituent are similar to those described in relation to R¹ to R⁴ of Formula (A). These substituents may be bonded to each other and form a ring, and in this case, examples of the compound represented by Formula (N) include a compound having a crosslinked cyclic skeleton such as an adamantane derivative in which at least one carbon atom constituting a ring is substituted by a nitrogen atom.

The aryl group and the alkyl group related to R¹¹ to R¹⁶ and the alkoxy group related to R¹³ and R¹⁴ may have a substituent. Examples of the substituent include the substituent described in relation to R¹ to R⁴ of Formula (A) and an oxygen atom (═O).

Among compounds represented by Formula (N), a compound having a structure represented by Formula (N1) or a structure represented by Formula (N2) is preferable from the viewpoint of further improving the light resistance of a light absorption anisotropic film.

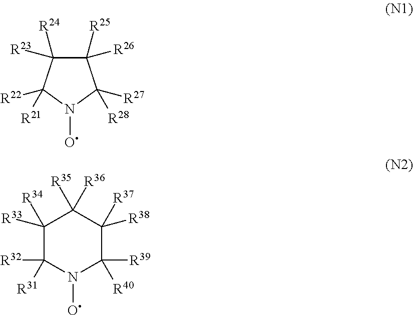

In Formula (N1), R²¹ to R²⁸ each independently represent a hydrogen atom or a substituent. In a case where two or more groups selected from the group consisting of R²¹ to R²⁸ are substituents, two or more substituents may be connected to each other and form a ring.

Examples of the substituents represented by R²¹ to R²⁸ include the substituent described in relation to R¹ to R⁴ of Formula (A) and an oxygen atom (═O). In a case where R²¹ to R²⁸ represent oxygen atoms, both R²¹ and R²² represent one oxygen atom (═O), both R²³ and R²⁴ represent one oxygen atom (═O), both R²⁵ and R²⁶ represent one oxygen atom (═O), and both R²⁷ and R²⁸ represent one oxygen atom (═O).

Among the above examples, R²¹ to R²⁸ each independently preferably represent a hydrogen atom, an oxygen atom, a hydroxy group, an alkyl group, an alkoxy group, an aryl group, an aryloxy group, a carbamoyl group, a carboxy group, an acyloxy group, a carbonamide group, or a sulfonamide group. Among these, an alkyl group, carbonamide group, or sulfonamide group having 1 to 20 carbon atoms is more preferable from the viewpoint of the fact that the oxidant obtains similar hydrophilicity or hydrophobicity to the dichroic dye compound, and thus the light resistance improving effect can be further exhibited.

In a case where two or more substituents are connected to each other among R²¹ to R²⁸ and form a ring, the compound represented by Formula (N1) preferably has the above-described crosslinked cyclic skeleton. Such a compound having a crosslinked cyclic skeleton itself has high activity, and thus can exhibit a good oxidation suppression function. Accordingly, the light resistance of a light absorption anisotropic film is further improved.

In Formula (N2), R³¹ to R⁴⁰ each independently represent a hydrogen atom or a substituent. In a case where two or more groups selected from the group consisting of R³¹ to R⁴⁰ are substituents, two or more substituents may be connected to each other and form a ring.

Examples of the substituents represented by R³¹ to R⁴⁰ include the substituent described in relation to R¹ to R⁴ of Formula (A) and an oxygen atom (═O). In a case where R³¹ to R⁴⁰ represent oxygen atoms, both R³¹ and R³² represent one oxygen atom (═O), both R³³ and R³⁴ represent one oxygen atom (═O), both R³⁵ and R³⁶ represent one oxygen atom (═O), both R³⁷ and R³⁸ represent one oxygen atom (═O), and both R³⁹ and R⁴⁰ represent one oxygen atom (═O).

Among the above examples, R³¹ to R⁴⁰ each independently preferably represent a hydrogen atom, an oxygen atom, an alkyl group, a hydroxy group, an alkoxy group, an aryl group, an aryloxy group, a carbamoyl group, a carboxy group, an acyloxy group, a carbonamide group, or a sulfonamide group. Among these, an alkyl group, carbonamide group, or sulfonamide group having 1 to 20 carbon atoms is more preferable from the viewpoint of the fact that the oxidant obtains similar hydrophilicity or hydrophobicity to the dichroic dye compound, and thus the light resistance improving effect can be further exhibited.

In a case where two or more substituents are connected to each other among R³¹ to R⁴⁰ and form a ring, the compound represented by Formula (N2) preferably has the above-described crosslinked cyclic skeleton. Such a compound having a crosslinked cyclic skeleton itself has high activity, and thus can exhibit a good oxidation suppression function. Accordingly, the light resistance of a light absorption anisotropic film is further improved.

A compound represented by Formula (N3) is also used as the oxidant having an N-oxyl structure.

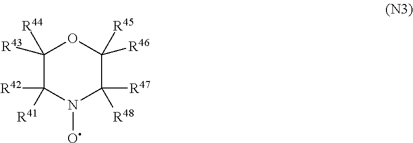

In Formula (N3), R⁴¹ to R⁴⁸ each independently represent a hydrogen atom or a substituent. In a case where two or more groups selected from the group consisting of R⁴¹ to R⁴⁸ are substituents, two or more substituents may be connected to each other and form a ring.

Examples of the substituents represented by R⁴¹ to R⁴⁸ include the substituent described in relation to R¹ to R⁴ of Formula (A) and an oxygen atom (═O). In a case where R⁴¹ to R⁴⁸ represent oxygen atoms, both R⁴¹ and R⁴² represent one oxygen atom (═O), both R⁴³ and R⁴⁴ represent one oxygen atom (═O), both R⁴⁵ and R⁴⁶ represent one oxygen atom (═O), and both R⁴⁷ and R⁴⁸ represent one oxygen atom (═O).

Among the above examples, R⁴¹ to R⁴⁸ each independently preferably represent a hydrogen atom, an oxygen atom, an alkyl group, a hydroxy group, an alkoxy group, an aryl group, an aryloxy group, a carbamoyl group, a carboxy group, an acyloxy group, a carbonamide group, or a sulfonamide group. Among these, an alkyl group, carbonamide group, or sulfonamide group having 1 to 20 carbon atoms is more preferable from the viewpoint of the fact that the oxidant obtains similar hydrophilicity or hydrophobicity to the dichroic dye compound, and thus the light resistance improving effect can be further exhibited.

In a case where two or more substituents are connected to each other among R⁴¹ to R⁴⁸ and form a ring, the compound represented by Formula (N3) preferably has the above-described crosslinked cyclic skeleton. Such a compound having a crosslinked cyclic skeleton itself has high activity, and thus can exhibit a good oxidation suppression function. Accordingly, the light resistance of a light absorption anisotropic film is further improved.

A compound represented by Formula (N4) is also used as the oxidant having an N-oxyl structure.

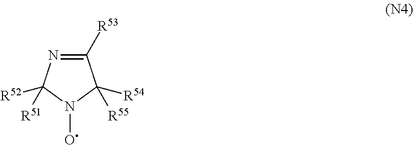

In Formula (N4), R⁵¹ to R⁵⁵ each independently represent a hydrogen atom or a substituent. In a case where two or more groups selected from the group consisting of R⁵¹ to R⁵⁵ are substituents, two or more substituents may be connected to each other and form a ring. Since the substituents represented by R⁵¹ to R⁵⁵ are similar to the substituent described in relation to R¹ to R⁴ of Formula (A), the description thereof will be omitted.

Among the above examples, R⁵¹ to R⁵⁵ each independently preferably represent a hydrogen atom, an alkyl group, a hydroxy group, an alkoxy group, an aryl group, an aryloxy group, a carbamoyl group, a carboxy group, an acyloxy group, a carbonamide group, or a sulfonamide group.

Specific examples of the oxidant having an N-oxyl structure are as follows, but not limited thereto.

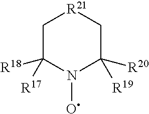

| No. | R¹⁷ | R¹⁸ | R¹⁹ | R²⁰ | R²¹ |
|---|---|---|---|---|---|
| N1-1 | CH₃ | CH₃ | CH₃ | CH₃ | CH₂ |
| N1-2 | CH₃ | CH₃ | CH₃ | CH₃ | O |
| N1-3 | CH₃ | CH₃ | CH₃ | CH₃ | —CH(COOH)— |
| N1-4 | CH₃ | CH₃ | CH₃ | CH₃ | —CH(COOC₂H₅)— |
| N1-5 | CH₃ | CH₃ | CH₃ | CH₃ | —CH(NHSO₂C₁₆H₃₃)— |
| N1-6 | CH₃ | CH₃ | CH₃ | CH₃ | C═O |
| N1-7 | CH₃ | CH₃ | CH₃ | CH₃ | —CH(OCOC₁₃H₂₇)— |
| N1-8 | CH₃ | CH₃ | CH₃ | CH₃ | —CH(OH)— |

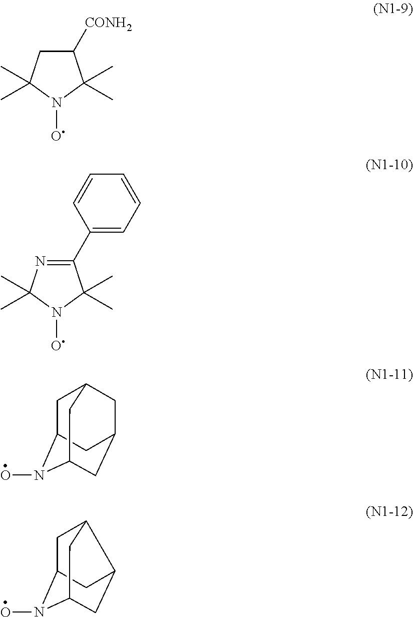

(Oxidant Having Amine Oxide Structure)

As the oxidant, an oxidant having an amine oxide structure may be used other than the oxidant having a quinone structure and the oxidant having an N-oxyl structure.

As the oxidant having an amine oxide structure, a compound represented by Formula (AO) is preferable from the viewpoint of further improving the light resistance of a light absorption anisotropic film.

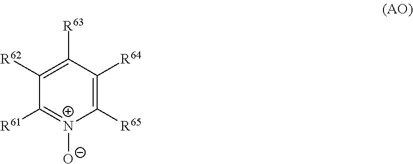

In Formula (AO), R⁶¹ to R⁶⁵ each independently represent a hydrogen atom or a substituent. In a case where two or more groups selected from the group consisting of R⁶¹ to R⁶⁵ are substituents, two substituents adjacent to each other (specifically, R⁶¹ and R⁶², R⁶² and R⁶³, R⁶³ and R⁶⁴, or R⁶⁴ and R⁶⁵) may be connected to each other and form an unsaturated condensed ring. The unsaturated condensed ring may have a substituent, and the substituent is similar to the substituent described in relation to R⁶¹ to R⁶⁵.

The substituents represented by R⁶¹ to R⁶⁵ are similar to the substituent described in relation to R¹ to R⁴ of Formula (A). Among the above examples, R⁶¹ to R⁶⁵ each independently preferably represent a hydrogen atom, an alkyl group, or a nitro group.

Specific examples of the oxidant having an amine oxide structure are as follows, but not limited thereto.

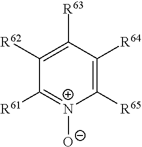

| No. | R⁶¹ | R⁶² | R⁶³ | R⁶⁴ | R⁶⁵ |
|---|---|---|---|---|---|
| AO-1 | H | H | H | H | H |
| AO-2 | H | H | CH₃ | H | H |
| AO-3 | H | H | NO₂ | H | H |
| AO-4 | CH₃ | H | H | H | CH₃ |

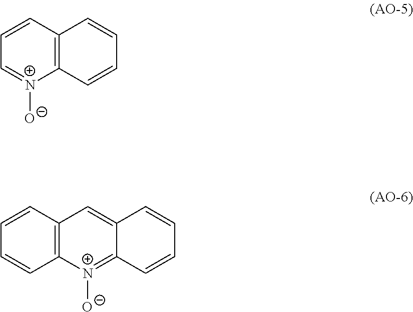 [SMILES: [O-][n+]1cccc2ccccc21 ; [O-][n+]1c2ccccc2cc2ccccc21]

<Dichroic Dye Compound Having Azo Group>

The coloring composition according to the first embodiment contains a dichroic dye compound having an azo group.

In the invention, a dichroic dye compound means a dye whose absorbance varies depending on the direction. In addition, dichroism and a dichroic ratio are calculated as a ratio of the absorbance of polarized light in an absorption axis direction with respect to the absorbance of polarized light in a polarization axis direction when the dichroic dye composition is used as a light absorption anisotropic film.

The dichroic dye compound having an azo group is not particularly limited as long as it has an azo group, and a conventionally known dichroic dye compound can be used.

Specific examples thereof include dichroic dye compounds having an azo group described in paragraphs [0067] to [0071] of JP2013-228706A, paragraphs [0008] to [0026] of JP2013-227532A, paragraphs [0008] to [0015] of JP2013-209367A, paragraphs [0045] to [0058] of JP2013-14883A, paragraphs [0013] to [0022] of JP2013-109090A, paragraphs [0009] to [0017] of JP2013-101328A, paragraphs [0052] to [0059] of JP2013-37353A, paragraphs [0050] to [0057] of JP2012-63387A, a paragraph [0018] of JP1999-305036A (JP-H11-305036A), paragraphs [0009] to [0011] of JP2001-133630A, and paragraphs [0030] to [0169] of JP2011-215337A.

The dichroic dye compound having an azo group preferably has liquid crystallinity, more preferably has thermotropic liquid crystallinity or lyotropic liquid crystallinity, and even more preferably has thermotropic liquid crystallinity. Here, thermotropic liquid crystallinity means a property of exhibiting liquid crystallinity by transition to a liquid crystalline phase by heat. The lyotropic liquid crystallinity means a property exhibiting liquid crystallinity by transition to a liquid crystalline phase by a concentration change.

As the dichroic dye compound having such thermotropic liquid crystallinity and having an azo group, for example, azo dyes described in paragraphs [0056] to [0219] of JP2011-237513A can be preferably used.

The dichroic dye compounds having an azo group may be used alone or in combination of two or more kinds thereof.

In a case where a dichroic dye compound having a partial structure represented by Formula (D1) is used as the dichroic dye compound having an azo group, the above-described oxidant having an N-oxyl structure is preferably used. Accordingly, the light resistance of a light absorption anisotropic film is further improved.

*—Ar¹N═N—Ar²ₙ* (D1)

In Formula (D1), Ar¹ and Ar² each independently represent an aromatic hydrocarbon ring or a heterocyclic ring, n represents an integer of 1, 3 or 4, and * represents a bonding position to another group. In a case where n is 3 or 4, a plurality of Ar²'s may be the same or different.

Regarding Ar¹ and Ar² positioned at both terminals of Formula (D1), all bonding hands at bonding positions * to another group are not directly bonded to an azo group That is, the bonding hand on the left side of Ar¹ of Formula (D1) is not directly bonded to an azo group, and the bonding hand on the right side of Ar² existing on the rightmost side of Formula (D1) is not directly bonded to an azo group.

Aromatic hydrocarbon groups represented by Ar¹ and Ar² may be monocyclic or have a condensed ring structure of two or more rings. The number of rings of the aromatic hydrocarbon ring is preferably 1 to 4, more preferably 1 to 2, and even more preferably 1 (that is, benzene ring).

Specific examples of the aromatic hydrocarbon rings include a benzene ring, an azulene ring, a naphthalene ring, a fluorene ring, an anthracene ring, and a tetracene ring. A benzene ring and a naphthalene ring are preferable, and a benzene ring is more preferable.

Heterocyclic rings represented by Ar¹ and Ar² may be aromatic or nonaromatic, and from the viewpoint of improving the dichroic ratio, aromatic heterocyclic rings are preferable.

Aromatic heterocyclic rings may be monocyclic or have a condensed ring structure of two or more rings. Examples of the atom other than carbon constituting an aromatic heterocyclic ring include a nitrogen atom, a sulfur atom, and an oxygen atom. In a case where an aromatic heterocyclic ring has more than one ring-constituent atoms other than carbon, these may be the same or different.

Specific examples of the aromatic heterocyclic ring include a pyridine ring, a thiophene ring, a quinolone ring, an isoquinoline ring, a thiazole ring, a benzothiadiazole ring, a phthalimide ring, a thienothiazole ring, a thienothiophene ring, and a thienooxazole ring, and a thienothiazole ring is preferable.

In a case where a dichroic dye compound having a partial structure represented by Formula (D2) is used as the dichroic dye compound having an azo group, the above-described oxidant having a quinone structure is preferably used. Accordingly, the light resistance of a light absorption anisotropic film is further improved.

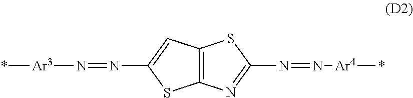

In Formula (D2), Ar³ and Ar⁴ each independently represent an aromatic hydrocarbon ring or a heterocyclic ring, and * represents a bonding position to another group. Since Ar³ and Ar⁴ are defined similarly to Ar¹ and Are in Formula (D1), the description thereof will be omitted.

Regarding Ar³ and Ar⁴, all bonding hands at bonding positions * to another group are not directly bonded to an azo group. That is, the bonding hand on the left side of Ar³ of Formula (D2) is not directly bonded to an azo group, and the bonding hand on the right side of Ar⁴ of Formula (D2) is not directly bonded to an azo group.

<Liquid Crystalline Compound>

The coloring composition according to the first embodiment preferably contains a liquid crystalline compound. In a case where the liquid crystalline compound is contained, it is possible to align the dichroic dye compound at a high alignment degree while suppressing the precipitation of the dichroic dye compound.

The liquid crystalline compound is a liquid crystalline compound other than the dichroic dye compound having an azo group.

Any one of a low-molecular-weight liquid crystalline compound and a high-molecular-weight liquid crystalline compound can be used as the liquid crystalline compound. Here, the “low-molecular-weight liquid crystalline compound” refers to a liquid crystalline compound having no repeating unit in the chemical structure. The “high-molecular-weight liquid crystalline compound” refers to a liquid crystalline compound having a repeating unit in the chemical structure.

Examples of the low-molecular-weight liquid crystalline compound include those described in JP2013-228706A.

Examples of the high-molecular-weight liquid crystalline compound include thermotropic liquid crystalline polymers described in JP2011-237513A and dichroic dye polymers having thermotropic liquid crystallinity described in JP2016-4055A. In addition, the high-molecular-weight liquid crystalline compound may have a crosslinkable group (for example, an acryloyl group and a methacryloyl group) at the terminal.

The liquid crystalline compounds may be used alone or in combination of two or more kinds thereof.

The content of the liquid crystalline compound is preferably 0.1 to 10,000 parts by mass, more preferably 1 to 5,000 parts by mass, and even more preferably 10 to 1,000 parts by mass with respect to 100 parts by mass of the content of the dichroic dye compound having an azo group in the coloring composition. In a case where the content of the liquid crystalline compound is within the above range, the dichroic ratio of a light absorption anisotropic film is improved.

<Solvent>

The coloring composition according to the first embodiment preferably contains a solvent from the viewpoint of workability or the like.

Examples of the solvent include organic solvents such as ketones (for example, acetone, 2-butanone, methyl isobutyl ketone, cyclopentanone, and cyclohexanone), ethers (for example, dioxane, tetrahydrofuran, and cyclopentyl methyl ether), aliphatic hydrocarbons (for example, hexane), alicyclic hydrocarbons (for example, cyclohexane), aromatic hydrocarbons (for example, benzene, toluene, xylene, and trimethylbenzene), halogenated carbons (for example, dichloromethane, trichloromethane (chloroform), dichloroethane, dichlorobenzene, and chlorotoluene), esters (for example, methyl acetate, ethyl acetate, and butyl acetate), alcohols (for example, ethanol, isopropanol, butanol, and cyclohexanol), cellosolves (for example, methyl cellosolve, ethyl cellosolve, and 1,2-dimethoxyethane), cellosolve acetates, sulfoxides (for example, dimethyl sulfoxide), amides (for example, dimethylformamide and dimethylacetamide), and heterocyclic compounds (for example, pyridine), and water. These solvents may be used alone or in combination of two or more kinds thereof.

Among these solvents, organic solvents are preferably used, and halogenated carbons or ketones are more preferably used.

In a case where the coloring composition contains a solvent, the content of the solvent is preferably 70 to 99.5 mass %, more preferably 85 to 99.0 mass %, and even more preferably 80 to 97 mass % with respect to the total mass of the coloring composition.

<Interface Improver>

The coloring composition according to the first embodiment may contain an interface improver. Due to the interface improver contained, the smoothness of the coating surface is improved and the alignment degree is improved. Otherwise, cissing and unevenness are suppressed, and thus an improvement in the in-plane uniformity is anticipated.

As the interface improver, a dichroic dye compound having an azo group, or a material making a liquid crystalline compound horizontal on the coating surface side is preferable, and compounds (horizontal alignment agents) described in paragraphs [0253] to [0293] of JP2011-237513A can be used.

The interface improvers may be used alone in combination of two or more kinds thereof.

In a case where the coloring composition contains an interface improver, the content of the interface improver is preferably 0.001 to 10 parts by mass, and preferably 0.01 to 5 parts by mass with respect to 100 parts by mass of the dichroic dye compound having an azo group in the coloring composition.

<Polymerization Initiator>

The coloring composition according to the first embodiment may contain a polymerization initiator.

The polymerization initiator is not particularly limited, and a photosensitive compound, that is, a photopolymerization initiator is preferable.

As the photopolymerization initiator, various kinds of compounds can be used with no particular limitation. Examples of the photopolymerization initiator include α-carbonyl compounds (the specifications of U.S. Pat. Nos. 2,367,661A and 2,367,670A), acyloin ethers (the specification of U.S. Pat. No. 2,448,828A), aromatic acyloin compounds substituted by α-hydrocarbon (the specification of U.S. Pat. No. 2,722,512A), polynuclear quinone compounds (the specifications of U.S. Pat. Nos. 3,046,127A and 2,951,758A), combinations of triarylimidazole dimers and p-aminophenyl ketones (the specification of U.S. Pat. No. 3,549,367A), acridine and phenazine compounds (the specifications of JP1985-105667A (JP-S60-105667A) and U.S. Pat. No. 4,239,850A), oxadiazole compounds (the specification of U.S. Pat. No. 4,212,970A), and acylphosphine oxide compounds (JP1988-40799B (JP-S63-40799B), JP1993-29234B (JP-H5-29234B), JP1998-95788B (JP-H10-95788B), and JP1998-29997B (JP-H10-29997B)).

A commercially available product can also be used as the photopolymerization initiator, and examples thereof include IRGACURE 184, IRGACURE 907, IRGACURE 369, IRGACURE 651, IRGACURE 819, IRGACURE OXE-01, and IRGACURE OXE-02 manufactured by BASF SE.

The polymerization initiators may be used alone or in combination of two or more kinds thereof.

In a case where the coloring composition contains a polymerization initiator, the content of the polymerization initiator is preferably 0.01 to 50 parts by mass, and more preferably 0.1 to 25 parts by mass with respect to 100 parts by mass of the dichroic dye compound having an azo group in the coloring composition.

### Second Embodiment

A coloring composition according to a second embodiment contains the above-described dichroic dye compound having an azo group and a singlet oxygen quencher.

The coloring composition according to the second embodiment is the same as the coloring composition according to the first embodiment, except that a singlet oxygen quencher is contained in place of the oxidant. In the description of the coloring composition according to the second embodiment, differences from the coloring composition according to the first embodiment will be described only.

<Singlet Oxygen Quencher>

The coloring composition according to the second embodiment contains a singlet oxygen quencher. A singlet oxygen quencher is a compound which reacts with and deactivates singlet oxygen.

The singlet oxygen quencher functions to improve the above-described light resistance of a light absorption anisotropic film, and also functions to improve the moisture-heat resistance of a light absorption anisotropic film.

The content of the singlet oxygen quencher is preferably 0.1 to 100 parts by mass, more preferably 1 to 50 parts by mass, and even more preferably 1 to 40 parts by mass with respect to 100 parts by mass of the dichroic dye compound having an azo group in the coloring composition. In a case where the content of the singlet oxygen quencher is within the above range, the light resistance of a light absorption anisotropic film is further improved.

The singlet oxygen quencher is not particularly limited, and examples thereof include metal salts such as nickel benzenesulfonate, nickel p-toluenesulfonate, nickel dimethyldithiocarbamate, nickel di-n-butyldithiocarbamate, metal complexes such as tetrabutyl phosphonium bis(1,2-benzenedithiolate)nickelate (III) and tetrabutyl phosphonium bis(4-methyl-1,2-benzenedithiolate)nickelate (III), and diimmonium salt compounds. Among these, diimmonium salt compounds are preferable.

The singlet oxygen quenchers may be used alone or in combination of two or more kinds thereof.

(Diimmonium Salt Compound)

As the diimmonium salt compound, a compound represented by Formula (D) is preferable from the viewpoint of further improving the light resistance of a light absorption anisotropic film.

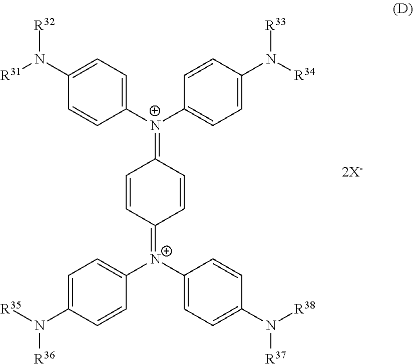

In Formula (D), R³¹ to R³⁸ each independently represent a hydrogen atom or a hydrocarbon group. X⁻ represents a monovalent anion.

Examples of the hydrocarbon group related to R³¹ to R³⁸ include an alkyl group and an aryl group, and an alkyl group is preferable.

The alkyl group is preferably a linear, branched, or cyclic alkyl group having 1 to 8 carbon atoms, and examples thereof include methyl, ethyl, propyl, isopropyl, n-butyl, t-butyl, isobutyl, cyclopentyl, cyclohexyl, n-pentyl, n-heptyl, n-octyl, and 2-ethylhexyl. Among these, a linear or branched alkyl group having 1 to 8 carbon atoms is preferable.

The aryl group preferably has 6 to 10 carbon atoms, and examples thereof include phenyl and naphthyl. Phenyl is more preferable.

The hydrocarbon group related to R³¹ to R³⁸ may have a substituent. Specific examples thereof include substituents described in paragraphs [0025] to [0034] of JP2011-38007A.

Examples of the monovalent anion of X⁻ include ClO₄⁻, PF₆⁻, and BF₄⁻. Two X⁻ in Formula (D) may be the same or different.

As the monovalent anion of X⁻, anions described in paragraphs [0016] to [0023] of JP2011-38007A can also be used.

Specific examples of the diimmonium salt compound are as follows, but not limited thereto.

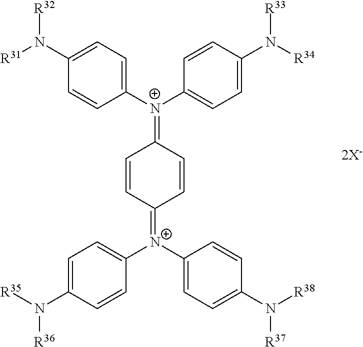

| No. | R³¹ | R³² | R³³ | R³⁴ | R³⁵ | R³⁶ | R³⁷ | R³⁸ | X⁻ |
|---|---|---|---|---|---|---|---|---|---|
| D-1 | CH₃ | CH₃ | CH₃ | CH₃ | CH₃ | CH₃ | CH₃ | CH₃ | ClO₄⁻ |
| D-2 | n-C₄H₉ | n-C₄H₉ | n-C₄H₉ | n-C₄H₉ | n-C₄H₉ | n-C₄H₉ | n-C₄H₉ | n-C₄H₉ | PF₆⁻ |
| D-3 | n-C₄H₉ | n-C₄H₉ | n-C₄H₉ | n-C₄H₉ | n-C₄H₉ | n-C₄H₉ | n-C₄H₉ | n-C₄H₉ | ClO₄⁻ |
| D-4 | C₂H₅ | C₂H₅ | C₂H₅ | C₂H₅ | C₂H₅ | C₂H₅ | C₂H₅ | C₂H₅ | BF₄⁻ |

[Light Absorption Anisotropic Film]

The light absorption anisotropic film according to the invention is formed using the above-described coloring composition.

Examples of the method of manufacturing the light absorption anisotropic film according to the invention include a method including, in order, a step of forming a coating film by applying the coloring composition to a base (hereinafter, also referred to as “coating film forming step”) and a step of aligning a liquid crystalline component contained in the coating film (hereinafter, also referred to as “alignment step”).

Hereinafter, the method of manufacturing the light absorption anisotropic film will be described for each step.

<Coating Film Forming Step>

The coating film forming step is a step of forming a coating film by applying the coloring composition to a base.

By using a coloring composition containing the above-described solvent, or a liquid material such as a molten liquid obtained by heating or the like of a coloring composition, the coloring composition is easily applied to the base.

Examples of the method of applying the coloring composition include known methods such as a roll coating method, a gravure printing method, a spin coating method, a wire bar coating method, an extrusion coating method, a direct gravure coating method, a reverse gravure coating method, a die coating method, a spray method, and an ink jet method.

In this aspect, an example has been given in which the coloring composition is applied to the base, but the invention is not limited thereto. For example, the coloring composition may be applied to an alignment film provided on the base. Details of the alignment film will be described later.

<Alignment Step>

The alignment step is a step of aligning a liquid crystalline component contained in the coating film. Thus, a light absorption anisotropic film is obtained.

The alignment step may have a drying treatment. Through the drying treatment, a component such as a solvent can be removed from the coating film. The drying treatment may be performed by a method of leaving the coating film for a predetermined time at room temperature (for example, natural drying), or a heating and/or air blowing method.

Here, the liquid crystalline component contained in the coloring composition may be aligned by the above-described coating film forming step or drying treatment. For example, in an aspect in which the coloring composition is prepared as a coating liquid containing a solvent, the coating film is dried to remove the solvent from the coating film, and thus a coating film having light absorption anisotropy (that is, light absorption anisotropic film) is obtained.

A heating treatment to be described later may not be performed in a case where the drying treatment is performed at a temperature of not lower than a temperature at which the liquid crystalline component contained in the coating film transits to a liquid crystalline phase.

The temperature at which the liquid crystalline component contained in the coating film transits to a liquid crystalline phase is preferably 10° C. to 250° C., and more preferably 25° C. to 190° C. in view of manufacturing suitability or the like. The transition temperature is preferably 10° C. or higher since a cooling treatment or the like for lowering the temperature to a temperature range in which the liquid crystalline phase is exhibited is not required. In addition, the transition temperature is preferably 250° C. or lower since even in an isotropic liquid state with a temperature higher than the temperature range in which the liquid crystalline phase is exhibited, high temperature is not required, and thus the waste of thermal energy and the deformation, degeneration, or the like of the substrate can be reduced.

The alignment step preferably has a heating treatment. Accordingly, the liquid crystalline component contained in the coating film can be aligned, and thus the coating film after the heating treatment can be preferably used as a light absorption anisotropic film.

The heating treatment is preferably performed at 10° C. to 250° C., and more preferably at 25° C. to 190° C. in view of manufacturing suitability or the like. The heating time is preferably 1 to 300 seconds, and more preferably 1 to 60 seconds.

The alignment step may have a cooling treatment to be performed after the heating treatment. The cooling treatment is a treatment for cooling the coating film after the heating to about room temperature (20° C. to 25° C.). Accordingly, the alignment of the liquid crystalline component contained in the coating film can be fixed. The cooling means is not particularly limited, and the cooling can be performed by a known method.

By the above steps, a light absorption anisotropic film can be obtained.

In this aspect, examples of the method of aligning the liquid crystalline component contained in the coating film include the drying treatment and the heating treatment, but are not limited thereto, and a known alignment treatment can be used.

<Other Steps>

The method of manufacturing a light absorption anisotropic film may have a step of curing the light absorption anisotropic film (hereinafter, also referred to as “curing step”) after the alignment step. Accordingly, a light absorption anisotropic film having excellent durability is obtained.

The curing step is performed by, for example, heating and/or light irradiation (exposure). Among these, light irradiation is preferably performed to conduct the curing step.

As the light source used for curing, various light sources can be used such as infrared rays, visible light, and ultraviolet rays, and ultraviolet rays are preferable. In the curing, ultraviolet rays may be applied during heating, or may be applied via a filter which transmits only a component with a specific wavelength.

In a case where the exposure is performed during heating, although depending on the temperature at which the liquid crystalline component contained in the light absorption anisotropic film transits to a liquid crystalline phase, the heating temperature during the exposure is preferably 25° C. to 140° C.

In addition, the exposure may be performed under a nitrogen atmosphere. In a case where the light absorption anisotropic film is cured by radical polymerization, inhibition of the polymerization by oxygen is reduced, and thus the exposure is preferably performed under a nitrogen atmosphere.

The film thickness of the light absorption anisotropic film is preferably 0.1 to 5.0 μm, and more preferably 0.3 to 1.5 μm. Although depending on the concentration of the dichroic dye compound in the coloring composition, a light absorption anisotropic film having an excellent absorbance is obtained in a case where the film thickness is 0.1 μm or greater, and a light absorption anisotropic film having an excellent transmittance is obtained in a case where the film thickness is 5.0 μm or less.

[Laminate]

A laminate according to the invention has a base and the light absorption anisotropic film formed on the base. The laminate according to the invention may further have a λ/4 plate formed on the light absorption anisotropic film.

In addition, the laminate according to the invention preferably has an alignment film between the base and the light absorption anisotropic film.

Hereinafter, the constituent layers of the laminate will be described.

<Base>

The base can be selected in accordance with usage of the light absorption anisotropic film, and examples thereof include glass and a polymer film. The light transmittance of the base is preferably 80% or greater.

In a case where a polymer film is used as the base, an optically isotropic polymer film is preferably used. As specific examples and preferable aspects of the polymer, those described in a paragraph [0013] of JP2002-22942A can be applied. In addition, even a conventionally known polymer such as polycarbonate or polysulfone in which birefringence is likely to be developed can also be used by reducing the developability through molecular modification described in WO00/26705A.

<Light Absorption Anisotropic Film>

Since the light absorption anisotropic film is as described above, the description thereof will be omitted.

<λ/4 Plate>

The “λ/4 plate” is a plate having a λ/4 function, and is specifically, a plate having a function of converting linearly polarized light with a specific wavelength into circularly polarized light (or converting circularly polarized light into linearly polarized light).

Specific examples of the λ/4 plate include US2015/0277006A.

For example, in an aspect in which the λ/4 plate has a single layer structure, specific examples of the plate include a retardation film in which an optically anisotropic layer having a λ/4 function is provided on a stretched polymer film or a support. In an aspect in which the λ/4 plate has a multilayered structure, specific examples of the plate include a broadband λ/4 plate having a laminate of a λ/4 plate and a λ/2 plate.

The λ/4 plate and the light absorption anisotropic film may be provided in contact with each other, or another layer may be provided between the λ/4 plate and the light absorption anisotropic film. Examples of the layer include a pressure sensitive layer and an adhesive layer.

<Alignment Film>

The laminate according to the invention may have an alignment film between the base and the light absorption anisotropic film.

As the alignment film, any layer may be used as long as it allows the liquid crystalline component contained in the coloring composition according to the invention to have a desired alignment state on the alignment film.

The alignment film can be provided by means of a rubbing treatment on the film surface with an organic compound (preferably a polymer), oblique vapor deposition of an inorganic compound, forming a layer having microgrooves, or accumulation of an organic compound (for example, ω-tricosanoic acid, dioctadecylmethylammonium chloride or methyl stearate) by the Langmure-Blogette method (LB film). Furthermore, there have been known alignment films having an aligning function imparted thereto by applying an electrical field, applying a magnetic field, or light irradiation. In the invention, among these, an alignment film formed by a rubbing treatment is preferable in view of easy control of a pretilt angle of the alignment film, and a photo-alignment film formed by light irradiation is also preferable in view of alignment uniformity.

(Rubbed Alignment Film)

The polymer material used for an alignment film formed by a rubbing treatment is described in many literatures, and many commercially available products are available. In the invention, polyvinyl alcohol or polyimide, or derivatives thereof can be preferably used. Regarding the alignment film, the description in the 24th line on page 43 to 8th line on page 49 in WO01/88574A1 can be referred to. The thickness of the alignment film is preferably 0.01 to 10 μm, and more preferably 0.01 to 1 μm.

(Photo-Alignment Film)

The photo-alignment material used for an alignment film formed by light irradiation is described in many literatures. In the invention, preferable examples thereof include azo compounds described in JP2006-285197A, JP2007-76839A, JP2007-138138A, JP2007-94071A, JP2007-121721A, JP2007-140465A, JP2007-156439A, JP2007-133184A, JP2009-109831A, JP3883848B, and JP4151746B, aromatic ester compounds described in JP2002-229039A, maleimide and/or alkenyl-substituted nadimide compounds having photo-alignment units described in JP2002-265541A and JP2002-317013A, photocrosslinkable silane derivatives described in JP4205195B and JP4205198B, and photocrosslinkable polyimides, polyamides, and esters described in JP2003-520878A, JP2004-529220A, and JP4162850B. Azo compounds, photocrosslinkable polyimides, polyamides, and esters are more preferable.

To a photo-alignment film formed from the above-described material, linearly polarized light or unpolarized light is applied to manufacture a photo-alignment film.

In this specification, the “linearly polarized light irradiation” and the “unpolarized light irradiation” are operations for causing a photoreaction to the photo-alignment material. The wavelength of the light used is not particularly limited as long as the wavelength varies depending on the photo-alignment material used and is a wavelength necessary for the photoreaction. The peak wavelength of the light used for light irradiation is preferably 200 nm to 700 nm, and ultraviolet light having a light peak wavelength of 400 nm or less is more preferable.

The light source used for light irradiation is a usually used light source, and examples thereof include lamps such as a tungsten lamp, a halogen lamp, a xenon lamp, a xenon flash lamp, a mercury lamp, a mercury/xenon lamp, and a carbon arc lamp, various lasers [for example, a semiconductor laser, a helium/neon laser, an argon ion laser, a helium/cadmium laser, and an YAG (yttrium/aluminum/garnet) laser], light emitting diodes, and cathode ray tubes.

As means for obtaining linearly polarized light, a method using a polarizing plate (for example, an iodine polarizing plate, a dichroic dye polarizing plate, or a wire grid polarizing plate), a method using a prism-based element (for example, a GLAN-THOMSON prism) or a reflective polarizer using a BREWSTER angle, or a method using light emitted from a polarized laser light source can be employed. Only light having a necessary wavelength may be selectively applied by using a filter, a wavelength conversion element, or the like.

In a case where linearly polarized light is used as light for irradiation, a method of irradiating the alignment film with light from an upper surface or a rear surface in a direction vertical or oblique to the alignment film surface is employed. Although the incidence angle of the light varies depending on the photo-alignment material, the incidence angle is preferably 0° to 90° (vertical), and more preferably 40° to 90°.

In a case where unpolarized light is used, the alignment film is irradiated with unpolarized light from an oblique direction. The incidence angle of the light is preferably 10° to 80°, more preferably 20° to 60°, and even more preferably 30° to 50°.

The irradiation time is preferably 1 minute to 60 minutes, and more preferably 1 minute to 10 minutes.

In a case where patterning is required, a method of performing light irradiation using a photomask as many times as necessary for pattern formation, or a pattern writing method using laser beam scanning can be employed.

<Usage>

The laminate according to the invention can be used as a polarizing element (polarizing plate). For example, it can be used as a linearly polarizing plate or a circularly polarizing plate.

In a case where the laminate according to the invention has no optically anisotropic layer such as the λ/4 plate, the laminate can be used as a linearly polarizing plate. In a case where the laminate according to the invention has the λ/4 plate, the laminate can be used as a circularly polarizing plate.

[Image Display Device]

An image display device according to the invention has the above-described light absorption anisotropic film or the above-described laminate.

The display element used for the image display device according to the invention is not particularly limited, and examples thereof include a liquid crystal cell, an organic electroluminescence (hereinafter, abbreviated as “EL”), a display panel, and a plasma display panel.

Among these, a liquid crystal cell or an organic EL display panel is preferable, and a liquid crystal cell is more preferable. That is, as the image display device according to the invention, a liquid crystal display device using a liquid crystal cell as a display element, or an organic EL display device using an organic EL display panel as a display element is preferable, and a liquid crystal display device is more preferable.

<Liquid Crystal Display Device>

A liquid crystal display device as an example of the image display device according to the invention preferably has an aspect in which it has the above-described light absorption anisotropic film and a liquid crystal cell. More preferably, the liquid crystal display device has the above-described laminate (but including no λ/4 plate) and a liquid crystal cell.

In the invention, it is preferable that the light absorption anisotropic film (laminate) according to the invention be used as a polarizing element on the front side among light absorption anisotropic films (laminates) to be provided on both sides of a liquid crystal cell, and it is more preferable that the light absorption anisotropic film (laminate) according to the invention be used as polarizing elements on the front side and the rear side.

Hereinafter, the liquid crystal cell of the liquid crystal display device will be described in detail.

(Liquid Crystal Cell)

The liquid crystal cell used for the liquid crystal display device is preferably a vertical alignment (VA) mode, an optical compensated bend (OCB) mode, an in-plane-switching (IPS) mode, or a twisted nematic (TN) mode, but is not limited thereto.

In a TN mode liquid crystal cell, with no application of a voltage, rod-like liquid crystalline molecules are substantially horizontally aligned, and twist-aligned by 60° to 120°. The TN mode liquid crystal cell is most frequently used as a color thin film transistor (TFT) liquid crystal display device, and is described in many literatures.

In a VA mode liquid crystal cell, rod-like liquid crystalline molecules are substantially vertically aligned with no application of a voltage. The VA mode liquid crystal cell includes (1) a narrowly-defined VA mode liquid crystal cell in which rod-like liquid crystalline molecules are substantially vertically aligned with no application of a voltage, and are substantially horizontally aligned with the application of a voltage (described in JP1990-176625A (JP-H2-176625A)), (2) a (MVA mode) liquid crystal cell in which the VA mode is made into multi-domains in order to expand the viewing angle (described in SID97, Digest of tech. Papers (proceedings) 28 (1997) 845), (3) an (n-ASM mode) liquid crystal cell in which rod-like liquid crystalline molecules are substantially vertically aligned with no application of a voltage, and are twisted in multi-domains with the application of a voltage (described in the proceedings 58 and 59 of Japanese Liquid Crystal Conference (1998)), and (4) a SURVIVAL mode liquid crystal cell (announced at LCD internal 98). In addition, the VA mode liquid crystal cell may be any one of a patterned vertical alignment (PVA) type, an optical alignment type, and a polymer-sustained alignment (PSA) type. Details of these modes are described in JP2006-215326A and JP2008-538819A.

In an IPS mode liquid crystal cell, rod-like liquid crystalline molecules are substantially horizontally aligned with respect to a substrate, and the liquid crystalline molecules respond in a planar manner with the application of an electric field parallel to a substrate surface. The IPS mode displays a black image in a state in which no electric field is applied thereto, and the absorption axes of a pair of upper and lower polarizing plates are perpendicular to each other. A method of improving the viewing angle by reducing light leakage caused when a black image is displayed in an oblique direction using an optical compensation sheet is disclosed by JP1998-54982A (JP-H10-54982A), JP1999-202323A (JP-H11-202323A), JP1997-292522A (JP-H9-292522A), JP1999-133408A (JP-H11-133408A), JP1999-305217A (JP-H11-305217A), JP1998-307291A (JP-H10-307291A), and the like.

<Organic EL Display Device>

An organic EL display device as an example of the image display device according to the invention preferably has an aspect in which it has a light absorption anisotropic film, a λ/4 plate, and an organic EL display panel in this order from the visual recognition side.

More preferably, the organic EL display device has the above-described laminate having a λ/4 plate and an organic EL display panel in this order from the visual recognition side. In this case, the laminate has a base, an alignment film to be provided as necessary, a light absorption anisotropic film, and a λ/4 plate disposed in this order from the visual recognition side.

In addition, the organic EL display panel is a display panel configured using an organic EL element in which an organic light emitting layer (organic electroluminescence layer) is interposed between electrodes (between a cathode and an anode). The configuration of the organic EL display panel is not particularly limited, and a known configuration is employed.

### EXAMPLES

Hereinafter, the invention will be more specifically described based on examples. Materials, used amounts, ratios, treatment contents, treatment procedures, and the like shown in the following examples are able to be properly changed without departing from the gist of the invention. Therefore, the scope of the invention will not be restrictively interpreted by the following examples.

### Example 1

A light absorption anisotropic film of Example 1 was produced by applying a coloring composition 1 (see Table 1 to be described later) to an alignment film produced as follows.

<Production of Alignment Film>

A glass base (manufactured by Central Glass Co., Ltd., blue plate glass, size: 300 mm×300 mm, thickness: 1.1 mm) was washed with an alkaline detergent, and then pure water was poured thereto. After that, the glass base was dried.

The following alignment film forming composition 1 was applied to the glass base after the drying using a bar #12, and the applied alignment film forming composition 1 was dried for 2 minutes at 110° C. to form a coating film on the glass base.

The obtained coating film was subjected to a rubbing treatment (number of rotations of roller: 1,000 rotations/spacer thickness: 2.9 mm, stage speed: 1.8 m/min) once to form an alignment film 1 on the glass base.

Composition of Alignment Film Forming Composition 1

| | |
|---|---|
| Modified Polyvinyl Alcohol (see Formula (PVA-1)) | 2.00 parts by mass |
| Water | 74.08 parts by mass |
| Methanol | 23.86 parts by mass |
| Photopolymerization Initiator (IRGACURE 2959, manufactured by BASF SE) | 0.06 parts by mass |
| | (PVA-1) |
| 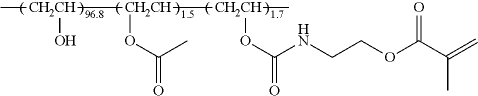 | |

The numerical value assigned to the repeating unit in Formula (PVA-1) represents a molar ratio of each repeating unit.

<Production of Light Absorption Anisotropic Film>

The obtained alignment film 1 was spin-coated with a coloring composition 1 (see Table 1 to be described later) by using a spin coater at a rotation speed of 1,000 rotations/10 sec to form a coating film. The coating film was dried for 30 seconds at room temperature (25° C.), and then further heated for 15 seconds at 180° C. Next, the coating film was cooled to room temperature, and thus a light absorption anisotropic film of Example 1 was produced on the alignment film 1.

### Examples 2 to 22, Comparative Examples 1 to 8

In each of Examples 2 to 22 and Comparative Examples 1 to 8, a light absorption anisotropic film was produced on the alignment film 1 in the same manner as in Example 1, except that the composition of the coloring composition was changed as shown in Table 1 to be described later.

[Evaluation Test]

<Evaluation of Light Resistance>

Regarding the light absorption anisotropic films of the examples and the comparative examples, light resistance was evaluated by measuring a dichroic ratio before and after a light resistance test. The smaller the decrease in the dichroic ratio after the light resistance test, the higher the light resistance. The dichroic ratios before and after the light resistance test are shown in the following Table 1.

(Method of Measuring Dichroic Ratio)

In a state in which a linear polarizer was inserted on the light source side of an optical microscope (manufactured by Nikon Corporation, product name “ECLIPSE E600 POL”), the light absorption anisotropic film of each of the examples and the comparative examples was set on a sample table, and using a multi-channel spectroscope (manufactured by Ocean Optics, Inc., product name “QE65000”), an absorbance of the light absorption anisotropic film in a wavelength band of 400 to 700 nm was measured to calculate a dichroic ratio by the following formula.

Dichroic Ratio (D0)=Az0/Ay0

In the above formula, “Az0” represents an absorbance with respect to the polarization in an absorption axis direction of the light absorption anisotropic film. “Ay0” represents an absorbance with respect to the polarization in a polarization axis direction of the light absorption anisotropic film.

(Light Resistance Test Method 1 (Light Resistance 1))

The glass base on which the light absorption anisotropic film of each of the examples and the comparative examples was formed was set on a light resistance test machine (manufactured by Suga Test Instruments Co., Ltd., trade name “XENON WEATHER METER X25”), and a surface of the glass base, on which the light absorption anisotropic film was formed, was irradiated with light emitted at 200,000 lux from a xenon lamp light source for 100 hours (cumulative light quantity: 20,000,000 lux/h). An ultraviolet cut filter of 370 nm was mounted on the Zenon lamp light source.

(Light Resistance Test Method 2 (Light Resistance 2))

A test for light resistance 2 was performed in the same manner as in the case of “light resistance 1”, except that the irradiation conditions were changed to perform the irradiation at 200,000 lux for 300 hours (cumulative light quantity: 60,000,000 lux/h).

[Evaluation Results]

The results of the above evaluation tests are shown in the following Table 1. In the evaluation results of light resistance 1 and light resistance 2 in Table 1, “-” represents that the light resistance test was not performed.

TABLE 1

| | | | Examples | | | | | | | | |
|---|---|---|---|---|---|---|---|---|---|---|---|
| Table 1 (1) | | | 1 | 2 | 3 | 4 | 5 | 6 | 7 | 8 | 9 |
| Composition | Liquid Crystalline | (A) | 4.60 | 4.60 | 4.60 | 4.60 | 4.60 | 4.60 | 4.60 | 4.60 | 4.60 |
| of Coloring | Compound | (B) | | | | | | | | | |
| Composition | | (C) | | | | | | | | | |
| | Dichroic Dye | (1) | 1.79 | | 1.79 | 1.79 | 1.79 | 1.79 | 1.79 | 1.79 | 1.79 |
| | Compound | (2) | | 1.79 | 1.79 | 1.79 | 1.79 | 1.79 | 1.79 | 1.79 | 1.79 |
| | | (3) | | | | 1.21 | 1.21 | 1.21 | 1.21 | 1.21 | 1.21 |
| | | (4) | | | | | | | | | |
| | Interface Improver | F1 | 0.04 | 0.04 | 0.04 | 0.04 | 0.04 | 0.04 | 0.04 | 0.04 | 0.04 |
| | Solvent | Chloroform | 93.46 | 93.46 | 93.46 | 93.46 | 93.46 | 93.46 | 93.46 | 93.46 | 93.46 |
| | Oxidant | X1 | | | | | | 0.40 | | | |
| | (quinone-based | X2 | 0.40 | 0.40 | 0.40 | 0.40 | | | | | |
| | oxidant) | X3 | | | | | 0.40 | | | | |
| | | X4 | | | | | | | 0.40 | | |
| | Oxidant | X5 | | | | | | | | 0.40 | |
| | (N-oxyl-based | X6 | | | | | | | | | |
| | oxidant) | X7 | | | | | | | | | |
| | | X8 | | | | | | | | | |
| | Singlet Oxide | X9 | | | | | | | | | 0.40 |
| | Quencher | | | | | | | | | | |
| | Amine-based Antioxidant | | | | | | | | | | |
| | Phenol-based Antioxidant | | | | | | | | | | |
| Evaluation | Light | Dichroic Ratio | 31 | 33 | 35 | 28 | 28 | 28 | 28 | 28 | 28 |
| Results | Resistance 1 | Before Light | | | | | | | | | |
| | (dichroic ratio) | Irradiation | | | | | | | | | |
| | | Dichroic Ratio | 31 | 32 | 35 | 27 | 28 | 28 | 27 | 27 | 26 |
| | | After Light | | | | | | | | | |
| | | Irradiation | | | | | | | | | |
| | Light | Dichroic Ratio | 31 | 33 | 35 | 28 | — | — | — | 28 | — |
| | Resistance 2 | Before Light | | | | | | | | | |
| | (dichroic ratio) | Irradiation | | | | | | | | | |
| | | Dichroic Ratio | 28 | 29 | 30 | 24 | — | — | — | 26 | — |
| | | After Light | | | | | | | | | |
| | | Irradiation | | | | | | | | | |

TABLE 2

| | | | Examples | | | | | | | | | | | | |
|---|---|---|---|---|---|---|---|---|---|---|---|---|---|---|---|
| Table 1 (2) | | | 10 | 11 | 12 | 13 | 14 | 15 | 16 | 17 | 18 | 19 | 20 | 21 | 22 |
| Composition | Liquid Crystalline | (A) | 4.60 | 4.60 | 4.60 | 4.60 | 4.60 | 4.60 | 4.60 | 4.60 | | | 4.60 | 4.60 | 4.60 |
| of Coloring | Compound | (B) | | | | | | | | | 4.60 | | | | |
| Composition | | (C) | | | | | | | | | | 4.60 | | | |
| | Dichroic Dye | (1) | | | | | 1.79 | 1.79 | 1.79 | 1.79 | 1.79 | 1.79 | | | 1.79 |
| | Compound | (2) | | | | | 1.79 | 1.79 | 1.79 | 1.79 | 1.79 | 1.79 | | | 1.79 |
| | | (3) | 1.21 | 1.21 | | | | | | | 1.21 | 1.21 | | | |
| | | (4) | | | 1.21 | 1.21 | | | | | | | 1.21 | 1.21 | 1.21 |
| | Interface Improver | F1 | 0.04 | 0.04 | 0.04 | 0.04 | 0.04 | 0.04 | 0.04 | 0.04 | 0.04 | 0.04 | | | |
| | Solvent | Chloroform | 93.46 | 93.46 | 93.46 | 93.46 | 93.46 | 93.46 | 93.46 | 93.46 | 93.46 | 93.46 | | | |
| | Oxidant | X1 | | | | | | | | | | | | | |
| | (quinone-based | X2 | | 0.40 | | 0.40 | | | | | 0.40 | 0.40 | | | |
| | oxidant) | X3 | | | | | | | | | | | | | |
| | | X4 | | | | | | | | | | | | | |
| | Oxidant | X5 | 0.40 | | 0.40 | | 0.40 | | | | | | | | |
| | (N-oxyl-based | X6 | | | | | | 0.40 | | | | | | | |
| | oxidant) | X7 | | | | | | | 0.40 | | | | 0.40 | | |
| | | X8 | | | | | | | | 0.40 | | | | 0.40 | 0.40 |
| | Singlet Oxide | X9 | | | | | | | | | | | | | |
| | Quencher | | | | | | | | | | | | | | |
| | Amine-based Antioxidant | | | | | | | | | | | | | | |
| | Phenol-based Antioxidant | | | | | | | | | | | | | | |
| Evaluation | Light | Dichroic Ratio | 28 | 28 | 36 | 36 | 35 | 35 | 36 | 37 | 26 | 21 | 37 | 39 | 35 |
| Results | Resistance 1 | Before Light | | | | | | | | | | | | | |
| | (dichroic ratio) | Irradiation | | | | | | | | | | | | | |
| | | Dichroic Ratio | 28 | 24 | 36 | 29 | 28 | 35 | 36 | 37 | 25 | 20 | 37 | 39 | 35 |
| | | After Light | | | | | | | | | | | | | |
| | | Irradiation | | | | | | | | | | | | | |
| | Light | Dichroic Ratio | — | 28 | 36 | 36 | — | 35 | 36 | 37 | — | — | 37 | 39 | 35 |
| | Resistance 2 | Before Light | | | | | | | | | | | | | |
| | (dichroic ratio) | Irradiation | | | | | | | | | | | | | |
| | | Dichroic Ratio | — | 20 | 33 | 25 | — | 32 | 33 | 34 | — | — | 35 | 38 | 34 |
| | | After Light | | | | | | | | | | | | | |
| | | Irradiation | | | | | | | | | | | | | |

TABLE 3

| | | | Comparative Examples | | | | | | | |
|---|---|---|---|---|---|---|---|---|---|---|
| Table 1 (3) | | | 1 | 2 | 3 | 4 | 5 | 6 | 7 | 8 |
| Composition | Liquid Crystalline | (A) | 4.60 | 4.60 | 4.60 | 4.60 | 4.60 | 4.60 | 4.60 | 4.60 |
| of Coloring | Compound | (B) | | | | | | | | |
| Composition | | (C) | | | | | | | | |
| | Dichroic Dye | (1) | 1.79 | | 1.79 | 1.79 | 1.79 | 1.79 | | |
| | Compound | (2) | | 1.79 | 1.79 | 1.79 | | | | |
| | | (3) | | | | 1.21 | | | 1.21 | |
| | | (4) | | | | | | | | 1.21 |
| | Interface Improver | F1 | 0.04 | 0.04 | 0.04 | 0.04 | 0.04 | 0.04 | 0.04 | 0.04 |
| | Solvent | | 93.46 | 93.46 | 93.46 | 93.46 | 93.46 | 93.46 | 93.46 | 93.46 |
| | Oxidant | X1 | | | | | | | | |
| | (quinone-based | X2 | | | | | | | | |
| | oxidant) | X3 | | | | | | | | |
| | | X4 | | | | | | | | |
| | Oxidant | X5 | | | | | | | | |
| | (N-oxyl-based | X6 | | | | | | | | |
| | oxidant) | X7 | | | | | | | | |
| | | X8 | | | | | | | | |
| | Singlet Oxide | X9 | | | | | | | | |
| | Quencher | | | | | | | | | |
| | Amine-based Antioxidant | | | | | | 0.40 | | | |
| | Phenol-based Antioxidant | | | | | | | 0.40 | | |
| Evaluation | Light | Dichroic Ratio | 31 | 33 | 35 | 28 | 31 | 31 | — | — |
| Results | Resistance 1 | Before Light | | | | | | | | |
| | (dichroic ratio) | Irradiation | | | | | | | | |
| | | Dichroic Ratio | 21 | 23 | 25 | 19 | 20 | 11 | — | — |
| | | After Light | | | | | | | | |
| | | Irradiation | | | | | | | | |
| | Light | Dichroic Ratio | 31 | 33 | 35 | 28 | — | — | 28 | 36 |
| | Resistance 2 | Before Light | | | | | | | | |
| | (dichroic ratio) | Irradiation | | | | | | | | |
| | | Dichroic Ratio | 20 | 21 | 22 | 16 | — | — | 11 | 16 |
| | | After Light | | | | | | | | |
| | | Irradiation | | | | | | | | |

Details of the components in Table 1 are as follows.

Liquid Crystalline Compound (A): A compound represented by Formula (A)

Liquid Crystalline Compound (B): A compound represented by Formula (B)

Liquid Crystalline Compound (C): A compound represented by Formula (C)

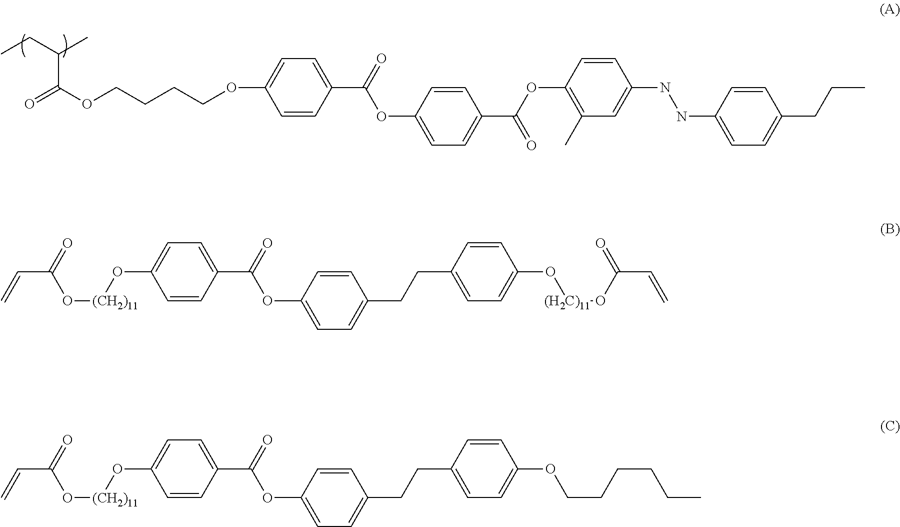

Dichroic Dye Compound (1): A compound represented by Formula (1)

Dichroic Dye Compound (2): A compound represented by Formula (2)

Dichroic Dye Compound (3): A compound represented by Formula (3)

Dichroic Dye Compound (4): A compound represented by Formula (4)

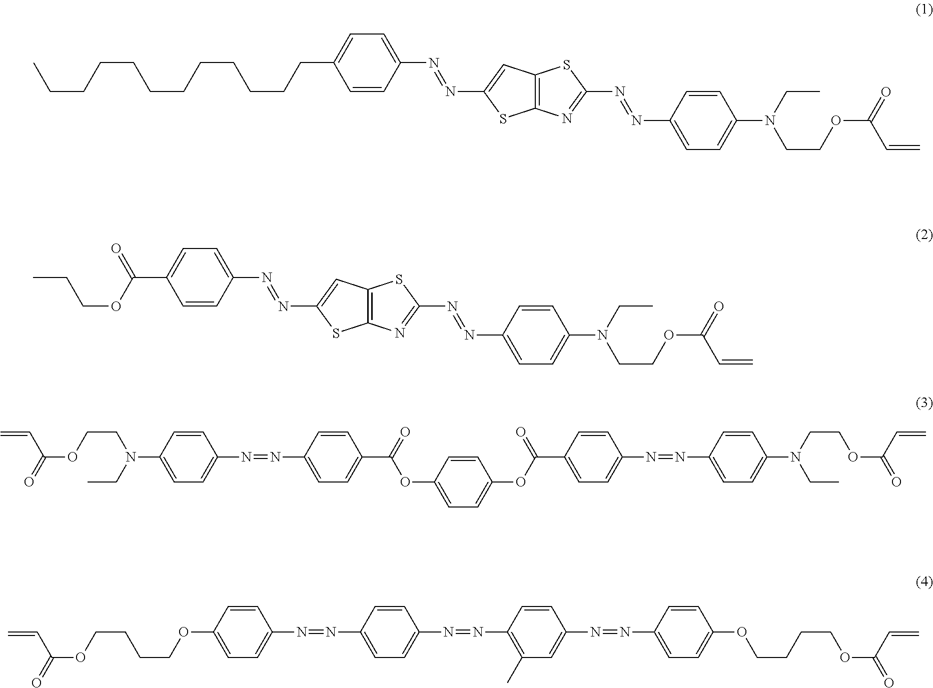

Interface Improver F1: A compound represented by Formula (F1)

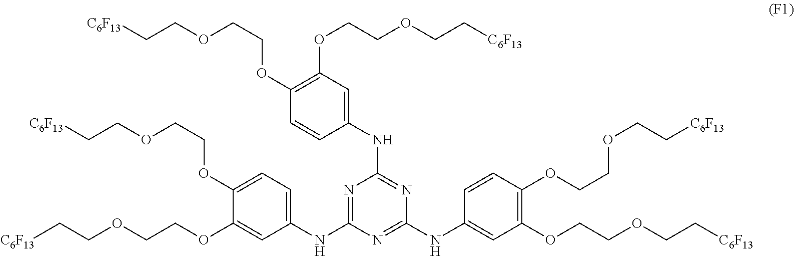

Solvent: Chloroform

X1: Quinone-based Oxidant (compound represented by Formula (X1))

X2: Quinone-based Oxidant (compound represented by Formula (X2))

X3: Quinone-based Oxidant (compound represented by Formula (X3))

X4: Quinone-based Oxidant (compound represented by Formula (X4))

X5: N-oxyl-based Oxidant (compound represented by Formula (X5))

X6: N-oxyl-based Oxidant (compound represented by Formula (X6))

X7: N-oxyl-based Oxidant (compound represented by Formula (X7))

X8: N-oxyl-based Oxidant (compound represented by Formula (X8))

X9: Singlet oxygen quencher (compound represented by Formula (X9))

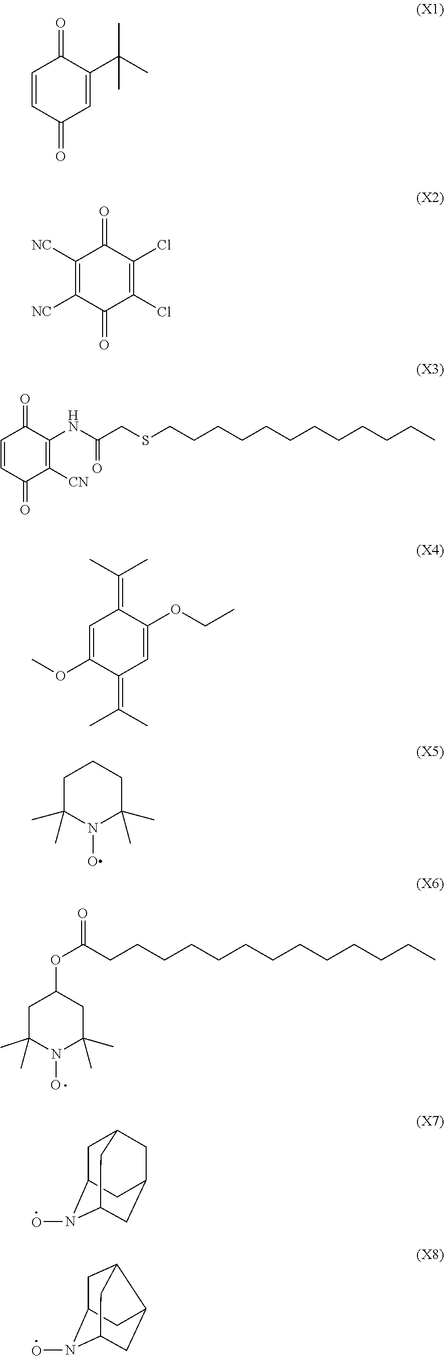

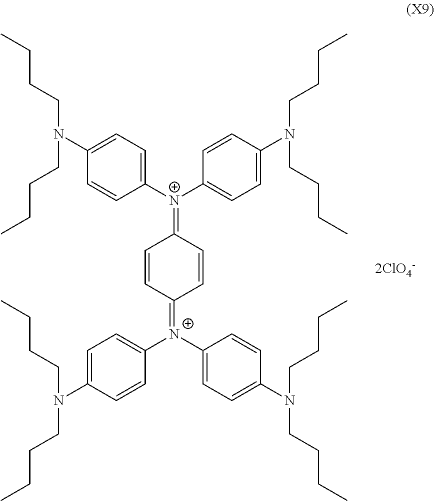 [SMILES: CCCCN(CCCC)c1ccc([N+](=C2C=CC(=[N+](c3ccc(N(CCCC)CCCC)cc3)c3ccc(N(CCCC)CCCC)cc3)C=C2)c2ccc(N(CCCC)CCCC)cc2)cc1]

Amine-based antioxidant: 2,2,6,6-tetramethyl-4-piperidyl-C12-21 and C18 unsaturated fatty acid ester (trade name CYASORB UV3853, manufactured by SUNCHEMICAL CO., LTD.)

Phenol-based antioxidant: 2,6-di-tert-butyl-p-cresol (BHT, manufactured by Tokyo Chemical Industry Co., Ltd.)

As shown in Table 1, it was found that a light absorption anisotropic film having excellent light resistance was obtained using a coloring composition containing: a dichroic dye compound having an azo group; and an oxidant or a singlet oxygen quencher (examples).

According to the comparison between Examples 1 to 3 and Examples 11 and 13, it was found that in a case where a quinone-based oxidant was used as an oxidant, the light resistance was more improved (the dichroic ratio decreasing rate was smaller) in a case where a dichroic dye compound having a partial structure represented by Formula (D2) was used (Examples 1 to 3) than in a case where a dichroic dye compound having a partial structure represented by Formula (D1) was used (Examples 11 and 13).

According to the comparison between Examples 10 and 14, it was found that in a case where an N-oxyl-based oxidant was used as an oxidant, the light resistance was more improved (the dichroic ratio decreasing rate was smaller) in a case where a dichroic dye compound having a partial structure represented by Formula (D1) was used (Example 10) than in a case where a dichroic dye compound having a partial structure represented by Formula (D2) was used (Example 14).

It was found that since the light absorption anisotropic films of Comparative Examples 1 to 4, 7 and 8 were formed using a coloring composition containing neither an oxidant nor a singlet oxygen quencher, the dichroic ratio after the light resistance test significantly decreased, and thus the light resistance deteriorated.

In addition, it was found that since the light absorption anisotropic films of Comparative Examples 5 and 6 were formed using a coloring composition containing various antioxidants, but containing neither an oxidant nor a singlet oxygen quencher, the dichroic ratio after the light resistance test significantly decreased, and thus the light resistance deteriorated.

### Example 23

On an alignment film 2 produced as follows, a light absorption anisotropic film was produced using a coloring composition of Example 23 to be described later.

<Production of Alignment Film 2>

A transparent base film (manufactured by FUJIFILM Corporation, cellulose acylate-based film, trade name “FUJITAC TG40UL”) was prepared and subjected to a saponification treatment to make a surface hydrophilic. Then, the following alignment film forming composition 2 was applied to the transparent base film using a bar #12, and the applied alignment film forming composition 2 was dried for 2 minutes at 110° C. to form an alignment film 2 on the transparent base film.

Composition of Alignment Film Forming Composition 2

| | | |
|---|---|---|
| Modified Vinyl Alcohol (Formula (PVA-1)) | 2.00 | parts by mass |
| Water | 74.08 | parts by mass |
| Methanol | 23.76 | parts by mass |
| Photopolymerization Initiator (IRGACURE 2959, | 0.06 | parts by mass |
| manufactured by BASF SE) | | |

<Production of Light Absorption Anisotropic Film>

The obtained alignment film 2 was spin-coated with a coloring composition of Example 23 (see the following composition) by using a spin coater at a rotation speed of 1,000 rotations/30 sec. Then, drying was performed for 30 seconds at room temperature, and thus a coating film was formed on the alignment film 2. Next, the obtained coating film was heated for 30 seconds at 140° C., and then cooled to room temperature. Next, the coating film was reheated to 80° C. and held for 30 seconds. Then, the coating film was cooled to room temperature. In this manner, a light absorption anisotropic film of Example 23 was produced on the alignment film 2.

Composition of Coloring Composition of Example 23

| | |
|---|---|
| Dichroic Dye Compound (5) (see Formula (5)) | 9.63 parts by mass |
| Dichroic Dye Compound (4) (see Formula (4)) | 7.92 parts by mass |
| Liquid Crystalline Compound P (see Formula (P)) | 40.11 parts by mass |
| Interface Improver F2 (see Formula (F2)) | 0.73 parts by mass |
| Interface Improver F3 (see Formula (F3)) | 0.73 parts by mass |
| Interface Improver F4 (see Formula (F4)) | 0.87 parts by mass |
| Tetrahydrofuran (solvent) | 799.0 parts by mass |
| Cyclopentanone (solvent) | 141.0 parts by mass |
| Oxidant (X-5) (see Formula (X-5)) | 0.87 parts by mass |
| 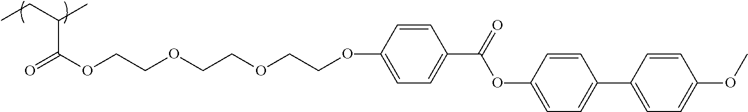 | (P) |
| 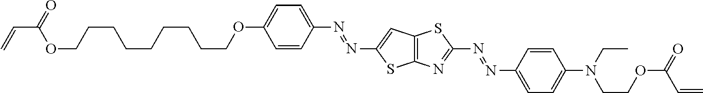 [SMILES: C=CC(=O)OCCCCCCCCCOc1ccc(/N=N/c2cc3sc(/N=N/c4ccc(N(CC)CCOC(=O)C=C)cc4)nc3s2)cc1] | (5) |
| 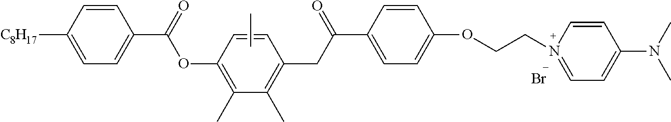 | F2 |
| 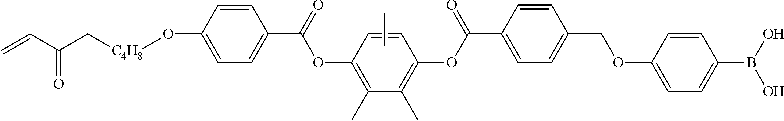 | F3 |
| 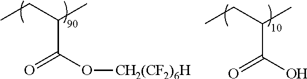 | F4 |

<Light Resistance of Light Absorption Anisotropic Film>

Light resistance 1 of the light absorption anisotropic film of Example 23 was measured in the same manner as in Examples 1 to 22, and the dichroic ratios before and after the light irradiation were 31.

It was found that a light absorption anisotropic film having excellent light resistance was obtained using a coloring composition containing: a dichroic dye compound having an azo group; and an oxidant.

What is claimed is:

1. A coloring composition comprising:
a dichroic dye compound having an azo group; and
an oxidant.

2. The coloring composition according to claim 1,
wherein the oxidant has at least one of a quinone structure or an N-oxyl structure.

3. The coloring composition according to claim 1,
wherein the dichroic dye compound having an azo group has a partial structure represented by Formula (D1), and
the oxidant has an N-oxyl structure,
*—Ar¹N═N—Ar²ₙ* (D1)
in Formula (D1), Ar¹ and Ar² each independently represent an aromatic hydrocarbon ring or a heterocyclic ring, n represents an integer of 1, 3, or 4, * represents a bonding position to another group, a plurality of Ar²'s may be the same or different in a case where n is 3 or 4, and regarding Ar¹ and Ar² positioned at both terminals of Formula (D1), all bonding hands at bonding positions * to another group are not directly bonded to an azo group.

4. The coloring composition according to claim 2,
wherein the N-oxyl structure is a structure represented by Formula (N1) or a structure represented by Formula (N2). 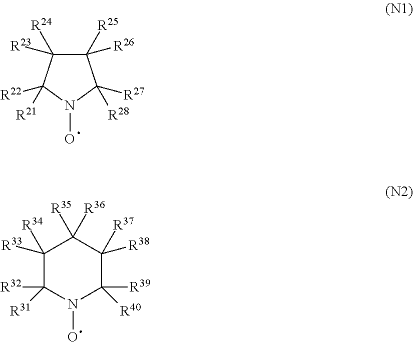
in Formula (N1), R²¹ to R²⁸ each independently represent a hydrogen atom or a substituent, and in a case where two or more groups selected from the group consisting of R²¹ to R²⁸ are substituents, two or more substituents may be connected to each other and form a ring,
in Formula (N2), R³¹ to R⁴⁰ each independently represent a hydrogen atom or a substituent, and in a case where two or more groups selected from the group consisting of R³¹ to R⁴⁰ are substituents, two or more substituents may be connected to each other and form a ring.

5. The coloring composition according to claim 1,
wherein the dichroic dye compound having an azo group has a partial structure represented by Formula (D2), and
the oxidant has a quinone structure, 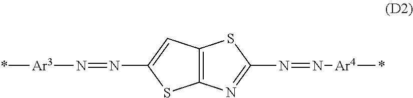
in Formula (D2), Ar³ and Ar⁴ each independently represent an aromatic hydrocarbon ring or a heterocyclic ring, * represents a bonding position to another group, and regarding Ar³ and Ar⁴, all bonding hands at bonding positions * to another group are not directly bonded to an azo group.

6. A coloring composition comprising:
a dichroic dye compound having an azo group; and
a singlet oxygen quencher.

7. The coloring composition according to claim 6,
wherein the singlet oxygen quencher is a diimmonium salt compound.

8. The coloring composition according to claim 1, further comprising:
a liquid crystalline compound.

9. A light absorption anisotropic film which is formed using the coloring composition according to claim 1.

10. A laminate comprising:
a base; and
the light absorption anisotropic film according to claim 9 which is formed on the base.

11. The laminate according to claim 10, further comprising:
a λ/4 plate which is formed on the light absorption anisotropic film.

12. An image display device comprising:
the light absorption anisotropic film according to claim 9.

13. The coloring composition according to claim 2,
wherein the dichroic dye compound having an azo group has a partial structure represented by Formula (D1), and
the oxidant has an N-oxyl structure,
*—Ar¹N═N—Ar²ₙ* (D1)
in Formula (D1), Ar¹ and Ar² each independently represent an aromatic hydrocarbon ring or a heterocyclic ring, n represents an integer of 1, 3, or 4, * represents a bonding position to another group, a plurality of Ar²'s may be the same or different in a case where n is 3 or 4, and regarding Ar¹ and Ar² positioned at both terminals of Formula (D1), all bonding hands at bonding positions * to another group are not directly bonded to an azo group.

14. The coloring composition according to claim 3,
wherein the N-oxyl structure is a structure represented by Formula (N1) or a structure represented by Formula (N2). 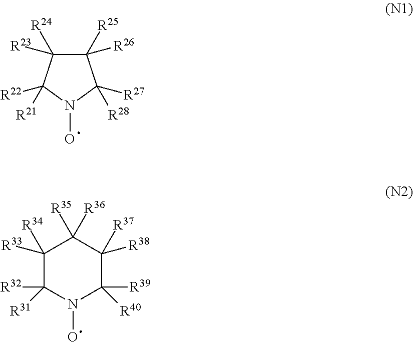
in Formula (N1), R²¹ to R²⁸ each independently represent a hydrogen atom or a substituent, and in a case where two or more groups selected from the group consisting of R²¹ to R²⁸ are substituents, two or more substituents may be connected to each other and form a ring,
in Formula (N2), R³¹ to R⁴⁰ each independently represent a hydrogen atom or a substituent, and in a case where two or more groups selected from the group consisting of R³¹ to R⁴⁰ are substituents, two or more substituents may be connected to each other and form a ring.

15. The coloring composition according to claim 13,
wherein the N-oxyl structure is a structure represented by Formula (N1) or a structure represented by Formula (N2). 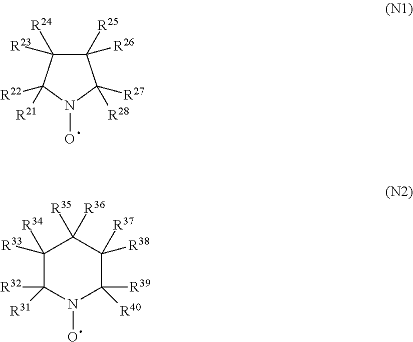
in Formula (N1), R²¹ to R²⁸ each independently represent a hydrogen atom or a substituent, and in a case where two or more groups selected from the group consisting of R²¹ to R²⁸ are substituents, two or more substituents may be connected to each other and form a ring,
in Formula (N2), R³¹ to R⁴⁰ each independently represent a hydrogen atom or a substituent, and in a case where two or more groups selected from the group consisting of R³¹ to R⁴⁰ are substituents, two or more substituents may be connected to each other and form a ring.

16. The coloring composition according to claim 2,
wherein the dichroic dye compound having an azo group has a partial structure represented by Formula (D2), and
the oxidant has a quinone structure, 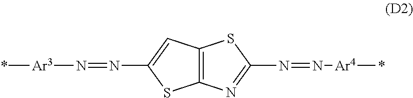
in Formula (D2), Ar³ and Ar⁴ each independently represent an aromatic hydrocarbon ring or a heterocyclic ring, * represents a bonding position to another group, and regarding Ar³ and Ar⁴, all bonding hands at bonding positions * to another group are not directly bonded to an azo group.

17. The coloring composition according to claim 2, further comprising:
a liquid crystalline compound.

18. The coloring composition according to claim 3, further comprising:
a liquid crystalline compound.

19. The coloring composition according to claim 4, further comprising:
a liquid crystalline compound.

20. An image display device comprising:
the laminate according to claim 10.
